(19) United States
(12) Patent Application Publication
(10) Pub. No.: US 2024/0274401 A1
(43) Pub. Date: Aug. 15, 2024

(54) SUBSTRATE POSITION MONITORING DEVICES

(71) Applicant: KLA Corporation, Milpitas, CA (US)

(72) Inventors: James Richard Bella, San Jose, CA (US); Earl Jensen, Santa Clara, CA (US); Alexander Buettner, Weilburg (DE); Emanuel Saerchen, Langgoens (DE)

(21) Appl. No.: 18/434,139

(22) Filed: Feb. 6, 2024

Related U.S. Application Data
(60) Provisional application No. 63/445,704, filed on Feb. 14, 2023.

(51) Int. Cl. H01J 37/22; G06T 7/13; G06T 7/55; H01J 37/32; H01L 21/68

(52) U.S. Cl. CPC H01J 37/222; G06T 7/13; G06T 7/55; H01J 37/32715; H01L 21/681; G06T 2207/30164; H01J 2237/024; H01J 2237/2007; H01J 2237/2445; H01J 2237/24578

(57) ABSTRACT

An instrumented substrate is used in a substrate processing system to determine offsets to a chuck and a focus ring. The instrumented substrate includes line sensors which generate line images and a controller which determines the offsets based on the line images. A substrate handler then repositions the instrumented substrate to reduce the offsets.

### CROSS-REFERENCE TO RELATED APPLICATIONS

The present application claims the benefit under 35 U.S.C. § 119(e) of U.S. Provisional Application Ser. No. 63/445,704, filed Feb. 14, 2023, titled “A SUBSTRATE POSITION MONITORING DEVICES”, which is incorporated herein by reference in the entirety.

### TECHNICAL FIELD

The present invention generally relates to a device for monitoring a wafer, and, more particularly, to a device for monitoring the position of a wafer.

### BACKGROUND

Precise positioning and positional information is critical for substrate processing and post-processing inspection. For example, an inspection tool may have an electron microscope or other electron beam system capable of resolving features at a very small micro- or nano-scale. The inspection tool may have a very narrow field of view that requires the substrate to be precisely positioned relative to the tool to locate particles or defects on the substrate and gather useful data. Precise information regarding the position of a substrate relative to the tool thus becomes critical for locating a particular small-scale defect, particle, or other area of interest on the substrate. Therefore, it would be advantageous to provide a device, system, and method that cures the shortcomings described above.

### SUMMARY

An instrumented substrate is described in accordance with one or more embodiments of the present disclosure. The instrumented substrate may include: a substrate including a substrate center; a power source; a communication interface; at least three position units, wherein each of the at least three position units include: an illumination source configured to generate illumination; and a line sensor configured to generate a plurality of line images based on the illumination, wherein the line sensor is aligned to the substrate center; and a controller including: a memory maintaining program instructions; and one or more processors configured to execute the program instructions causing the one or more processors to: receive the plurality of line images; and determine a substrate-to-chuck offset between the substrate center and a chuck center based on the plurality of line images.

In some aspects, the techniques described herein relate to an instrumented substrate, wherein the one or more processors determine the substrate-to-chuck offset by: detecting a plurality of chuck edges in the plurality of line images; determine a plurality of chuck non-concentricity offsets between the plurality of chuck edges; and determine the substrate-to-chuck offset based on the plurality of chuck non-concentricity offsets.

In some aspects, the techniques described herein relate to an instrumented substrate, wherein the program instructions cause the one or more processors to determine a substrate-to-ring offset based on the plurality of line images.

In some aspects, the techniques described herein relate to an instrumented substrate, wherein the substrate is a round substrate.

In some aspects, the techniques described herein relate to an instrumented substrate, wherein the substrate includes at least one of quartz, glass, silicon, silicon nitride, carbon fiber stabilized epoxy matrices, or a combination thereof.

In some aspects, the techniques described herein relate to an instrumented substrate, including one or more additional sensors, wherein the one or more additional sensors are configured to generate one or more sensor readings, wherein the controller is configured to detect a presence of a chuck based on the one or more sensor readings.

In some aspects, the techniques described herein relate to an instrumented substrate, wherein the one or more additional sensors include at least one of a pressure sensor, a multi-axis accelerometer, a multi-axis angular rate sensor, a temperature sensor, a light sensor, or a capacitive sensor.

In some aspects, the techniques described herein relate to an instrumented substrate, wherein, in response to the one or more sensor readings satisfying a trigger threshold, the one or more processors cause the illumination source to generate the illumination and cause the line sensor to generate the plurality of line images.

In some aspects, the techniques described herein relate to an instrumented substrate, wherein the substrate includes a diffusive region, wherein the diffusive region is disposed below the illumination source.

In some aspects, the techniques described herein relate to an instrumented substrate, wherein each of the at least three position units include a collimator, wherein the line sensor is imaged by the collimator.

In some aspects, the techniques described herein relate to an instrumented substrate, wherein the collimator includes a collimated hole array.

In some aspects, the techniques described herein relate to an instrumented substrate, wherein the collimator includes a stratified collimator.

In some aspects, the techniques described herein relate to an instrumented substrate, wherein the collimator is near field to the line sensor.

In some aspects, the techniques described herein relate to an instrumented substrate, wherein one or more reflectors are defined in a bottom surface of the substrate.

In some aspects, the techniques described herein relate to an instrumented substrate, wherein each of the at least three position units include a cylindrical lens, wherein the line sensor is imaged by the cylindrical lens.

In some aspects, the techniques described herein relate to an instrumented substrate, wherein the cylindrical lens is a stratified cylindrical lens that functions as a directional collimator.

In some aspects, the techniques described herein relate to an instrumented substrate, wherein each of the at least three position units include an optical element, wherein the optical element includes a beam splitter, an adsorber, an objective lens, and a condenser lens, wherein the line sensor is imaged by the optical element.

In some aspects, the techniques described herein relate to an instrumented substrate, wherein each of the at least three position units include a meta lens, wherein the line sensor is imaged by the meta lens.

In some aspects, the techniques described herein relate to an instrumented substrate, wherein each of the at least three position units include a microlens array, a first lens, a first folding mirror, a prism, a second lens, a second folding mirror, an aperture stop, a third lens, and a cylindrical lens; wherein the illumination follows an illumination path from the illumination source through the microlens array, the first lens, the first folding mirror, and the prism to a chuck; wherein the illumination follows an imaging path from the chuck through the prism, the second lens, the second folding mirror, the aperture stop, the third lens, and the cylindrical lens to the line sensor.

In some aspects, the techniques described herein relate to an instrumented substrate, wherein the illumination includes one or more incidence angles onto and one or more reflection angles from the chuck; wherein the one or more incidence angles are different than the one or more reflection angles.

In some aspects, the techniques described herein relate to an instrumented substrate, wherein at least two of the microlens array, the first lens, the first folding mirror, the prism, the second lens, the second folding mirror, the aperture stop, the third lens, or the cylindrical lens are part of a monolithic molded assembly.

In some aspects, the techniques described herein relate to an instrumented substrate, wherein each of the at least three position units include microlens array, a first lens, a first aperture stop, a prism, a second lens, a second aperture stop, and a third lens; wherein the illumination follows an illumination path from the illumination source through the microlens array, the first lens, the first aperture stop, and the prism to a chuck; wherein the illumination follows an imaging path from the chuck through the prism, the second lens, the second aperture stop, and the third lens to the line sensor.

In some aspects, the techniques described herein relate to an instrumented substrate, wherein the illumination includes one or more incidence angles onto and one or more reflection angles from the chuck; wherein the one or more incidence angles are different than the one or more reflection angles.

In some aspects, the techniques described herein relate to an instrumented substrate, wherein each of the at least three position units include a microlens array, a first lens, a first aperture stop, a second lens, a second aperture stop, and a third lens; wherein the illumination follows an illumination path from the illumination source through the microlens array, the first lens, and the first aperture stop to a chuck; wherein the illumination follows an imaging path from the chuck through the second lens, the second aperture stop, and the third lens to the line sensor.

In some aspects, the techniques described herein relate to an instrumented substrate, wherein the illumination includes one or more incidence angles onto and one or more reflection angles from the chuck; wherein the one or more incidence angles are at a same angle as the one or more reflection angles.

A substrate processing system is described in accordance with one or more embodiments of the present disclosure. The substrate processing system may include: a chuck including a chuck center; a focus ring; a substrate handler; and an instrumented substrate including: a substrate including a substrate center; a power source; a communication interface; at least three position units, wherein each of the at least three position units include: an illumination source configured to generate illumination; and a line sensor configured to generate a plurality of line images based on the illumination, wherein the line sensor is aligned to the substrate center; and a controller including: a memory maintaining program instructions; and one or more processors configured to execute the program instructions causing the one or more processors to: receive the plurality of line images; and determine a substrate-to-chuck offset between the substrate center and the chuck center based on the plurality of line images.

In some aspects, the techniques described herein relate to a substrate processing system, wherein the substrate handler is configured to receive the substrate-to-chuck offset from the instrumented substrate; wherein the substrate handler is configured to reposition the instrumented substrate on the chuck based on the substrate-to-chuck offset.

### BRIEF DESCRIPTION OF THE DRAWINGS

The numerous advantages of the disclosure may be better understood by those skilled in the art by reference to the accompanying figures in which:

FIG. 1A depicts a top view of an instrumented substrate, in accordance with one or more embodiments of the present disclosure.

FIG. 1B depicts a block diagram of a controller of an instrumented substrate, in accordance with one or more embodiments of the present disclosure.

FIG. 1C depicts a partial top view of an instrumented substrate, in accordance with one or more embodiments of the present disclosure.

FIG. 1D depicts a block diagram of sensor readings received by a trigger model, in accordance with one or more embodiments of the present disclosure.

FIG. 2A depicts a top view of a substrate processing system, in accordance with one or more embodiments of the present disclosure.

FIGS. 2B-2C depict cross section views of a substrate processing system, in accordance with one or more embodiments of the present disclosure.

FIGS. 3A-3C depict line images, in accordance with one or more embodiments of the present disclosure.

FIG. 4A depicts a cross section view of a substrate processing system, in accordance with one or more embodiments of the present disclosure.

FIG. 4B depicts a perspective view of a cylindrical lens, in accordance with one or more embodiments of the present disclosure.

FIGS. 5-6 depict cross section views of a substrate processing system, in accordance with one or more embodiments of the present disclosure.

FIG. 7 depicts a flow diagram of a method, in accordance with one or more embodiments of the present disclosure.

FIG. 8A depicts a partial top view of a substrate processing system including an instrumented substrate, a chuck, and a focus ring, in accordance with one or more embodiments of the present disclosure.

FIG. 8B depicts a cross section view of a substrate processing system including an instrumented substrate and a chuck, in accordance with one or more embodiments of the present disclosure.

FIG. 8C depicts a partial top view of a substrate processing system including an instrumented substrate, a chuck, and a focus ring, in accordance with one or more embodiments of the present disclosure.

FIG. 8D depicts a cross section view of a substrate processing system including an instrumented substrate and a chuck, in accordance with one or more embodiments of the present disclosure.

FIG. 9A depicts a partial top view of a substrate processing system including an instrumented substrate, a chuck, and a focus ring, in accordance with one or more embodiments of the present disclosure.

FIG. 9B depicts a cross section view of a substrate processing system including an instrumented substrate and a chuck, in accordance with one or more embodiments of the present disclosure.

FIG. 9C depicts a cross section view of a substrate processing system including an instrumented substrate and a chuck, in accordance with one or more embodiments of the present disclosure.

FIG. 10A depicts a partial top view of a substrate processing system including an instrumented substrate, a chuck, and a focus ring, in accordance with one or more embodiments of the present disclosure.

FIG. 10B depicts a cross section view of a substrate processing system including an instrumented substrate and a chuck, in accordance with one or more embodiments of the present disclosure.

### DETAILED DESCRIPTION OF THE INVENTION

The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure. Reference will now be made in detail to the subject matter disclosed, which is illustrated in the accompanying drawings.

Embodiments of the present disclosure are directed to an instrumented substrate. The instrumented substrate may be used in a substrate processing system to determine offsets from the instrumented substrate to a chuck and a focus ring. The instrumented substrate may include line sensors which generate line images and a controller which uses the line images to determine the offsets. A substrate handler may then reposition the instrumented substrate to reduce the offsets.

U.S. Pat. No. 9,620,400, titled “Position sensitive substrate device”; U.S. Patent Publication Number 2019/0172742, titled “Teaching method”; U.S. Patent Publication Number 2021/0252695, titled “Teaching method”; U.S. Pat. No. 7,289,230, titled “Wireless substrate-like sensor”; U.S. Pat. No. 11,668,601, titled “Instrumented substrate apparatus”; are each incorporated herein by reference in the entirety.

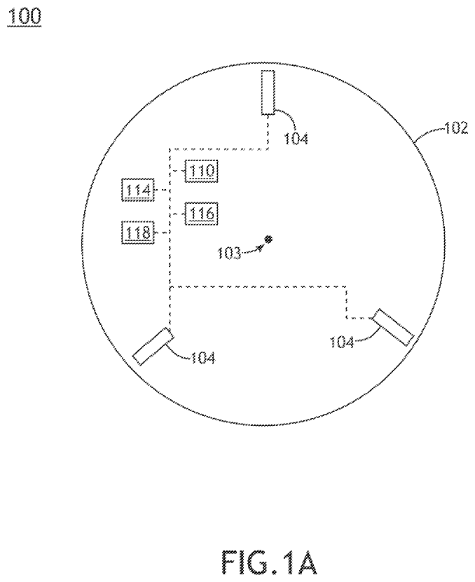

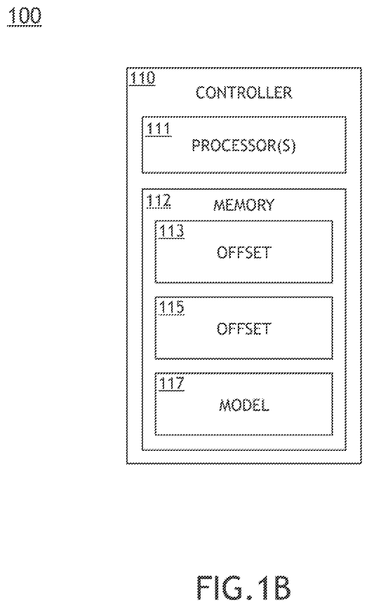

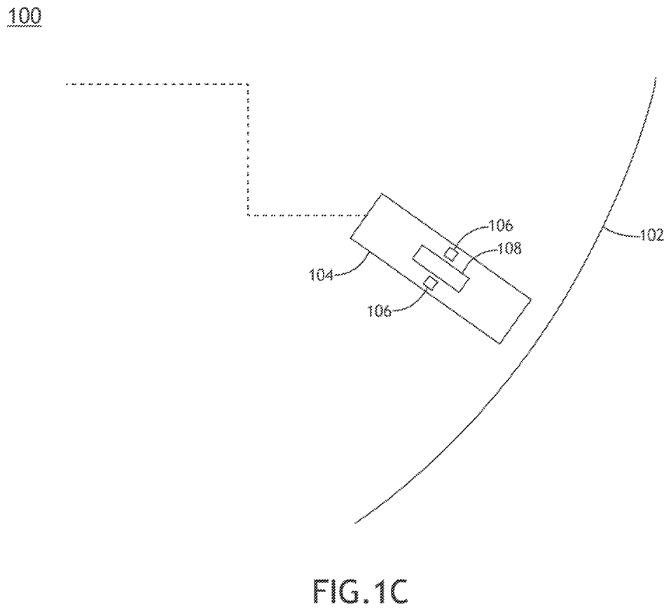

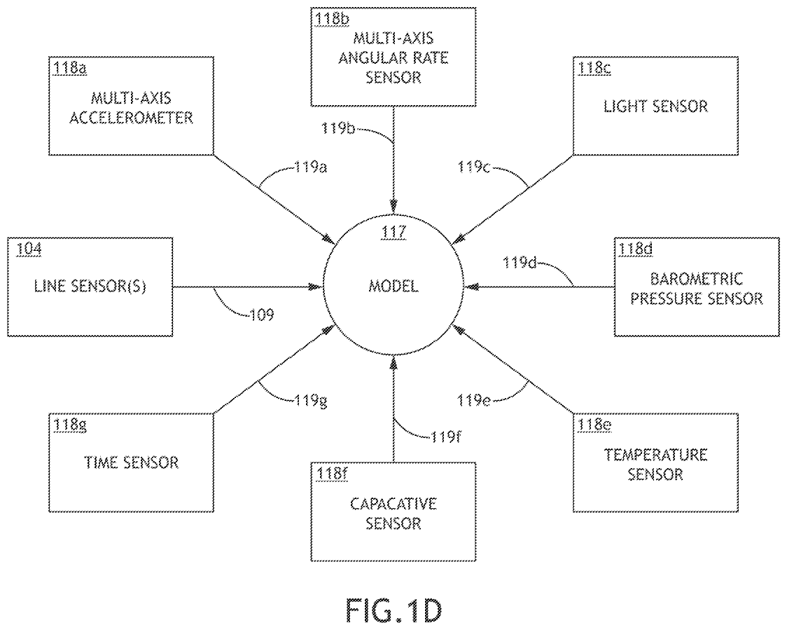

FIGS. 1A-1D illustrate an instrumented substrate 100, in accordance with one or more embodiments of the present disclosure. In embodiments, the instrumented substrate 100 may include a substrate 102, position units 104, a controller 110, a power source 114, a communication interface 116, and/or one or more sensors 118. For the purposes of the present disclosure, the instrumented substrate 100 may also be referred to as an instrumented substrate assembly, substrate device, instrumented wafer, instrumented wafer substrate, sensor wafer, substrate monitoring device, instrumented substrate device, inspection substrate, inspection wafer, measurement wafer, registration measuring substrate, registration wafer, and the like.

The substrate 102 may include any substrate known in the art of semiconductor fabrication monitoring. For example, the substrate 102 may include a wafer. For example, the substrate 102 may include a wafer structure formed from quartz, glass, silicon (e.g., single crystal silicon), silicon nitride, carbon fiber stabilized epoxy matrices, one or more ceramic materials, glass carbon fibers, one or more composite materials, or a combination thereof. For example, the substrate 102 may be formed from a composite material including two or more layers of material that may be bonded together or two or more materials that may be intermixed in a single layer or multiple layers. The substrate 102 may also be a composite material such as graphite/epoxy or a laminate formed from silicon, graphite/epoxy, silicon.

The substrate 102 may have physical parameters that approximate the physical parameters of a production substrate used in the manufacture of integrated circuits or other electronics. The substrate 102 may include a round substrate (e.g., a round wafer) having a selected diameter. For example, the substrate 102 may have a diameter between 25 and 450 mm. For instance, the substrate 102 may include a diameter between 100 and 300 mm. Additionally, the substrate 102 may have a thickness between 275 and 925 μm. In embodiments, the thickness may be based on the diameter. In embodiments, the substrate 102 has dimensions conforming to that of a Semiconductor Equipment and Materials International (SEMI®) wafer. The substrate 102 may also have a thickness that approximates the corresponding thickness of the production substrate, although the thickness may be slightly larger than the production substrate to accommodate additional electronics and/or other components of the instrumented substrate 100.

The substrate 102 may include a substrate center 103. The substrate center 103 may be disposed at the center or midpoint of the substrate 102. For example, the substrate center 103 may be at an equidistant point from the edge of the substrate 102.

The substrate 102 may include a top surface and/or a bottom surface. In embodiments, the top surface and/or the bottom surface of the substrate 102 may be planar. The bottom surface may also be referred to as a backside.

In embodiments, the position units 104 may include one or more edge position units. In embodiments, the position units 104 may be disposed on and/or embedded within the substrate 102. In embodiments, the position units 104 may include one or more optical units and may be configured to optically measure a position of the instrumented substrate 100 relative to another component.

In embodiments, the position units 104 may include two or more position units 104. For example, the instrumented substrate 100 may include at least three position units 104. In the case of two or more position units, the position units 104 may be arranged in a radial manner. For example, the position units 104 may be spaced evenly around an edge of the substrate 102. In embodiments, the position units 104 may be placed at one or more azimuths around the circumference of the substrate 102. The position units 104 may be disposed around the edge of the substrate 102 at an interval. The position units 104 may be placed around the edge of the substrate 102, with a preferred number being three and placed at a 120° angular spacing around the substrate 102. The position units 104 may be built onto or embedded into the substrate 102. The position units 104 may include one or more components, such as, but not limited to, illumination source 106, line sensor 108, and the like.

In embodiments, the illumination source 106 may be a light source. The illumination source 106 may generate illumination 107. The illumination 107 may include one or more selected wavelengths of light including, but not limited to, vacuum ultraviolet radiation (VUV), deep ultraviolet radiation (DUV), ultraviolet (UV) radiation, visible radiation, or infrared (IR) radiation. The illumination 107 may include any range of selected wavelengths. The illumination source 106 may include any suitable illumination source configured to generate the illumination 107. For example, the illumination source 106 may include one or more light-emitting diodes (LEDs). In embodiments, the illumination source 106 may include at least two LEDs arranged on opposing ends of the line sensor 108. The illumination source 106 may provide edge-lit illumination to the line sensor 108. The LEDs may include incoherent LEDs. In embodiments, the illumination source 106 may be a coherent laser light source. In embodiments, the illumination 107 may extend to illuminate all the pixels of the line sensors 108. For example, the position units 104 may include the illumination source 106 extending along the length of the line sensor 108.

In embodiments, the line sensors 108 may be linear sensors, linear imaging sensors, line detectors, and/or line imaging photonics sensors. The line sensors 108 may include any suitable line sensors, such as, but not limited to, complementary metal-oxide-semiconductor (CMOS) line sensors, Charge-coupled device (CCD) linear sensors, and the like.

The line sensor 108 may be aligned toward the substrate center 103. The line sensors 108 of the position units 104 may be unaligned or non-parallel relative to each other. In embodiments, an imaginary line extending from the line sensors 108 may intersect at the substrate center 103.

The line sensors 108 may include a linear array of photosensitive diodes (not depicted). The photosensitive diodes may include a selected pixel size. The pixel size may be rectangular in shape having a selected aspect ratio. The aspect ratio may be much larger in one dimension and smaller in another dimension. For example, the aspect ratio may be 1:16. For instance, the pixel size may be 120 by 7.5 μm. The aspect ratio of the line sensors 108 may enable detecting features along the length of the line sensors 108, where the length may correspond to the longer dimension of the aspect ratio. The aspect ratio of the line sensors 108 may or may not enable detecting features along the width of the line sensors 108, where the width may correspond to the shorter dimension of the aspect ratio.

The line sensors 108 may receive illumination 107. The line sensors 108 may receive the illumination 107 generated by the illumination source 106.

The line sensor 108 may generate line images 109. The line sensor 108 may generate the line images 109 based on the illumination 107 received. The line images 109 may be one-dimensional images. The line images 109 may be one-dimensional image in the longitudinal direction along the line sensor 108. One-dimensional images may be images with a linear resolution. The linear resolution may include 1 by N number of pixels, where N is an integer. For example, the line images 109 may include one-thousand or more pixels along the length of the line sensor 108. Each photodiode of the line sensor 108 may generate one pixel in the line images 109. For example, the line images may be one-dimensional image in a longitudinal direction along the photodiodes of the line sensor 108. The linear resolution may be high and may have enough signal to make a reasonable measurement in low light conditions. The line images 109 may also be data graphs showing signal as a function of pixel number (N).

The controller 110 may be communicatively coupled to the position units 104. For example, the controller 110 may be communicatively coupled to the line sensor 108. The controller 110 may be configured to receive data including, but not limited to, the line images 109. The controller 110 may be embedded into the substrate 102. The controller 110 may provide data collection and data storage functionality to the instrumented substrate 100.

The controller 110 may include one or more processors 111 and memory 112. The one or more processors 111 may be configured to execute program instructions maintained on the memory 112. In this regard, the one or more processors 111 of controller 110 may execute any of the various process steps described throughout the present disclosure.

In embodiments, the memory 112 may maintain a substrate-to-chuck offset 113 and/or a substrate-to-ring offset 115. The memory 112 may maintain the substrate-to-chuck offset 113 and/or the substrate-to-ring offset 115 after the controller 110 determine the respective offsets.

The substrate-to-chuck offset 113 and/or a substrate-to-ring offset 115 may be an offset, an offset correction, a corrective offset, a center offset, a center position offset, and/or a center offset correction solution. The substrate-to-chuck offset 113 and/or the substrate-to-ring offset 115 may be an X-Y distance. The X-Y distance may refer to X-direction offsets and Y-direction offsets defined with reference to an X-Y coordinate plane. The offsets may be measured from the substrate center 103.

In embodiments, the controller 110 may be configured to determine the substrate-to-chuck offset 113 and/or the substrate-to-ring offset 115. The controller 110 may determine the substrate-to-chuck offset 113 and/or the substrate-to-ring offset 115 based on the line images 109.

In embodiments, the controller 110 may determine the substrate-to-chuck offset 113 and/or the substrate-to-ring offset 115 based on the line images 109 by performing autocorrelation between the line images 109 from each of the position units 104. Thus, the controller 110 may include one or more data processing methods to perform autocorrelation between the different locations.

In embodiments, the controller 110 may determine the substrate-to-chuck offset 113 and/or a substrate-to-ring offset 115 as the line images 109 are received from the line sensor 108. Thus, the offsets may be determined in real time or in near-real time. Determining the substrate-to-chuck offset 113 and/or a substrate-to-ring offset 115 as the line images 109 are received may be beneficial to reduce the requirements of the memory 112. For example, the substrate-to-chuck offset 113 and/or a substrate-to-ring offset 115 may be stored in memory 112 without storing the line images 109 in memory.

The power source 114 may include one or more batteries, a wired power source, or the like. The power source 114 may provide power to any of the various components of the instrumented substrate 100. The power source 114 may optionally include one or more solar cells. The power source 114 may be embedded into the substrate 102. The power source 114 may provide power storage functionality to the instrumented substrate 100.

The communication interface 116 may include any wireline communication protocol (e.g., DSL-based interconnection, cable-based interconnection, T9-based interconnection, USB, and the like) or wireless communication protocol (e.g., GSM, GPRS, CDMA, EV-DO, EDGE, WiMAX, 3G, 4G, 4G LTE, 5G, Wi-Fi protocols, RF, Bluetooth, Intermediate System to Intermediate System (IS-IS), and the like). By way of another example, the communication interface 116 may include communication protocols including, but not limited to, radio frequency identification (RFID) protocols, open-sourced radio frequencies, and the like. By way of another example, the communication interface 116 may include inductive wireless communications and/or inductive wireless charging. For instance, the communication interface 116 may use On-Off keying and backscatter modulation for bidirectional data transfer together with inductive power transfer for battery charging. Accordingly, an interaction between the various devices may be determined based on one or more characteristics including, but not limited to, cellular signatures, IP addresses, MAC addresses, Bluetooth signatures, radio frequency identification (RFID) tags, and the like.

The sensors 118 may be placed on, embedded in, and/or disposed below the substrate 102. The sensors 118 may be additional sensors to the position units 104. The sensors 118 may generate one or more sensor readings. The sensors 118 may include, but are not limited to, multi-axis accelerometers 118a, multi-axis angular rate sensor 118b, light sensors 118c, barometric pressure sensors 118d, temperature sensors 118e, capacitive sensors 118f, and/or time sensors 118g.

The multi-axis accelerometer 118a may generate acceleration data 119a. The acceleration data 119a may include X, Y, Z motion of the instrumented substrate 100. The multi-axis accelerometer 118a may be an acceleration measuring type measuring 3-axis or 6-axis.

In embodiments, the multi-axis angular rate sensor 118b may be a gyroscope. The multi-axis angular rate sensor 118b may generate rotation rate data 119b. The rotation rate data 119b may be a rotation rate of the instrumented substrate 100. The multi-axis angular rate sensor 118b may measure 3-axis rotation rates.

The light sensor 118c may generate ambient light data 119c. The light sensor 118c may be a light measuring type with an excitation source. The light sensor 118c may be used in conjunction with any of the sensors 118 to determine a state of the instrumented substrate 100.

The barometric pressure sensor 118d may generate barometric pressure data 119d. The barometric pressure data 119d provides local pressure information of the instrumented substrate 100. The barometric pressure data 119d may be used for indexing load-lock or chamber transfers.

The temperature sensor 118e may generate temperature data 119e. The temperature data 119e may include a temperature of the substrate 102 or the like.

The capacitive sensor 118f may direct sample a proximity of the instrumented substrate 100 relative to another component. The capacitive sensor 118f may be a capacitive proximity sensor. The capacitive sensor 118f may generate capacitive data 119f.

The time sensor 118g may generate one or more time delay parameters 119g.

In embodiments, the controller 110 may include a trigger model 117. The trigger model 117 may be a triggering model and/or a trigger module. The trigger model 117 may be maintained in memory 112. The trigger model 117 may be executed by the processors 111.

The trigger model 117 may receive one or more sensor readings from the line sensors 108 and/or the sensors 118. For example, the trigger model 117 may receive the line images 109, the acceleration data 119a, the rotation rate data 119b, the ambient light data 119c, the barometric pressure data 119d, the temperature data 119e, the capacitive data 119f, and/or the time delay parameters 119g. The trigger model 117 may use the sensors readings as inputs to trigger one or more processes. For example, the controller 110 may use the sensor readings from the sensors 118 to determine whether the substrate 102 has reached a process chamber and may begin acquiring the line images 109.

The trigger model 117 may evaluate the sensor values from the line sensors 108 and/or the sensors 118 against one or more trigger thresholds. In embodiments, the trigger thresholds may be trigger conditions and/or trigger points. The trigger thresholds may be predefined a priori. For example, the trigger threshold may be user defined a priori. The controller 110 may cause the line sensors 108 to generate the line image 109 in response to the sensor values from the sensors 118 satisfying one or more trigger thresholds. For example, the controller 110 may cause the position units 104 to begin an edge sensor data collection sequence by generating the illumination 107 via the illumination source 106 and generating the line images 109 by the line sensors 108. Thus, the processors 111 may cause the illumination source 106 to generate the illumination 107 and cause the line sensors 108 to generate the line images 109 in response to one or more sensor readings satisfying the trigger threshold.

The trigger model 117 may include trigger thresholds based on sensors values from any of the sensors 118. The trigger thresholds may include trigger thresholds for the acceleration data 119a from the multi-axis accelerometer 118a, the rotation rate data 119b from the multi-axis angular rate sensor 118b, the ambient light data 119c from the light sensor 118c, the barometric pressure data 119d from the barometric pressure sensors 118d, the temperature data 119e from the temperature sensor 118e, the capacitive data 119f from the capacitive sensor 118f, and/or the time delay parameters 119g from the time sensor 118g. For example, the trigger model 117 may include a temperature threshold. The trigger model 117 may include a temperature threshold causing the instrumented substrate 100 to monitor the temperature of the environment based on the temperature data 119e. By way of another example, the trigger model 117 may use one or more time delay parameters.

In embodiments, the controller 110 may support multiple trigger thresholds within the trigger model 117. Supporting multiple trigger thresholds allows the controller 110 to collect a multitude of measurements. The trigger model 117 may evaluate multiple sensor inputs. The trigger threshold may be combined with any of the optical and mechanical configurations.

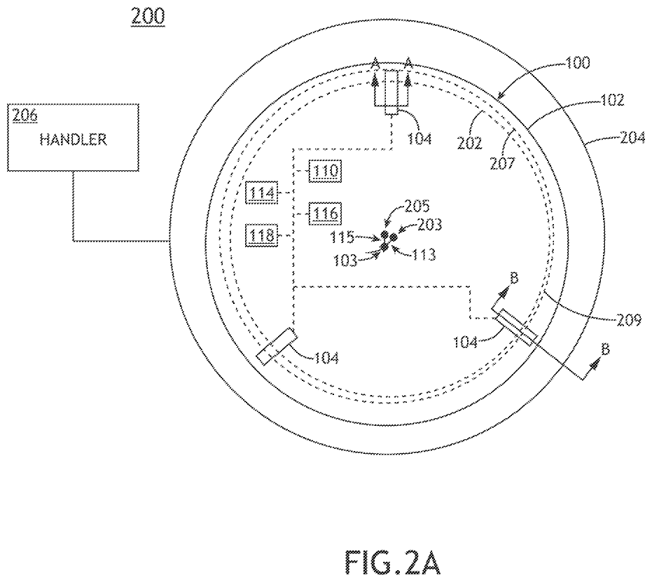

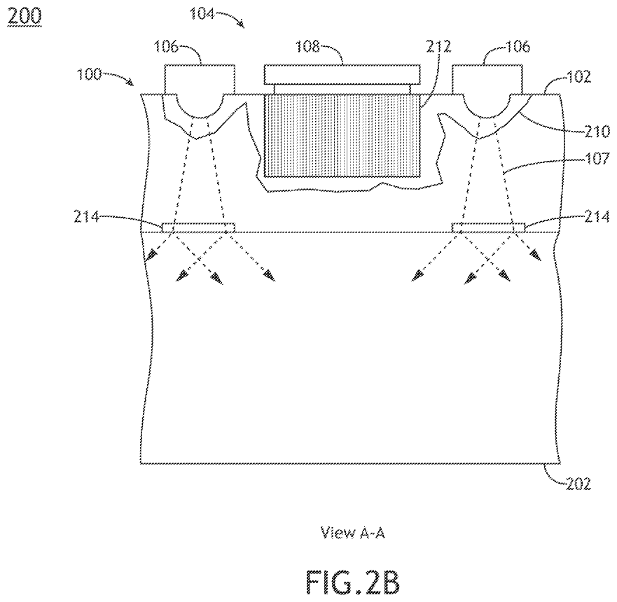

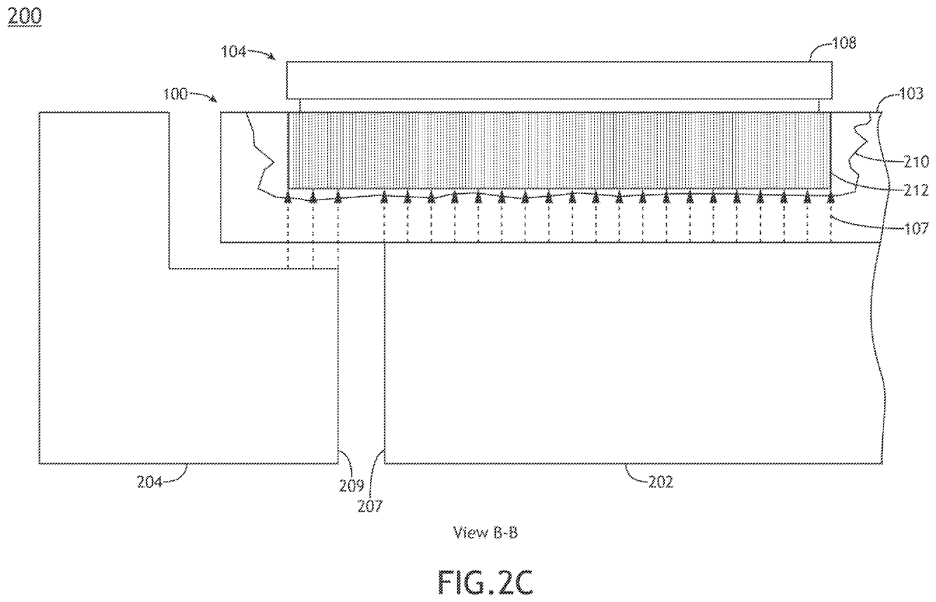

Referring now to FIGS. 2A-2C, a substrate processing system 200 is described, in accordance with one or more embodiments of the present disclosure. The substrate processing system 200 may include the instrumented substrate 100, a chuck 202, a focus ring 204, and a substrate handler 206. The substrate processing system 200 may be used in the manufacture of semiconductor devices and other electronic devices. In embodiments, the substrate processing system 200 may be part of a tool. The tool may be a tool for reviewing substrates, such as an inspection or metrology tool. The tool may include an electron microscope or other electron beam system. In embodiments, the substrate processing system 200 may be configured for processing using a plasma or the like.

in embodiments, the chuck 202 may be a process chuck, process chamber chuck, support surface, and/or a mounting table. In embodiments, the chuck 202 may include a mechanism to secure the instrumented substrate 100 in place. The chuck 202 may be configured to clamp and unclamp to the chuck 202 for securing the chuck 202. For example, the chuck 202 may be a mechanical chuck, a vacuum chuck, a magnetic chuck, an electrostatic chuck. In this example, the instrumented substrate 100 may be electrostatically clamped to the chuck 202.

The instrumented substrate 100 may be disposed on the chuck 202. For example, the instrumented substrate 100 may be disposed on the chuck 202 after being placed on the chuck 202 by a substrate handler 206. The chuck 202 may support the instrumented substrate 100. In embodiments, the chuck 202 may directly support the instrumented substrate 100. Thus, the chuck 202 may not be separated from the instrumented substrate 100 by an air-gap, forks, or the like. During operation, the bottom surface of the substrate 102 may be disposed on the chuck 202. It is desirable for the bottom surface of the substrate 102 to be planar for the sake of mechanical integrity and the prevention of backside gas leakage in case of the chuck 202 using electrostatics clamping. The prevention of backside gas leakage may not affect the fidelity of the line images 109. However, excessive backside gas leakage may cause fault tripping of the substrate processing system 200.

The chuck 202 may be a round chuck having a selected diameter. In embodiments, the diameter of the chuck 202 may be less than the diameter of the substrate 102. The chuck 202 may include a chuck center 203. The chuck center 203 may be disposed at the center or midpoint of the chuck 202. For example, the chuck center 203 may be at an equidistant point from chuck edge 207. The chuck 202 may also include the chuck edge 207. The chuck edge 207 may be an exterior curved edge wrapping around a cylindrical face of the chuck 202. The chuck edge 207 may connect to a top surface of the chuck 202 on which the substrate 102 is disposed.

In embodiments, the focus ring 204 may be an edge ring, a silicon ring, and/or a dielectric isolation ring. The focus ring 204 may be utilized in one or more plasma processes. For example, the focus ring 204 may constrain plasma and/or gas about the substrate 102 and/or the chuck 202.

The focus ring 204 may be a round ring having a selected diameter. In embodiments, the diameter of the focus ring 204 may be greater than the diameter of the substrate 102 and/or the chuck 202. The focus ring 204 may include a focus ring center 205. The focus ring center 205 may be disposed at the center or midpoint of the focus ring 204. For example, the focus ring center 205 may be disposed at an equidistant point from a focus ring edge 209. The focus ring 204 may also include the focus ring edge 209. The focus ring edge 209 may be an interior curved edge wrapping around a cylindrical face of the focus ring 204. The focus ring edge 209 may be an inner diameter of the focus ring 204.

In embodiments, the focus ring 204 may surround the chuck 202. For example, the focus ring 204 surrounds the chuck edge 207. For instance, the focus ring edge 209 may surround the chuck edge 207. The focus ring edge 209 may include a diameter which is larger than the diameter of the chuck edge 207. In embodiments, the substrate 102 and the position units 104 may overhang the chuck edge 207 and/or the focus ring edge 209. The substrate processing system 200 may include a gap defined between the chuck 202 and the focus ring 204. The gap may be defined by the chuck edge 207 and the focus ring edge 209. The illumination 107 may be lost to the gap defined between the chuck 202 and the focus ring 204 is not reflected to the line sensor 108.

The instrumented substrate 100 may be configured to generate the line images 109 of the chuck 202 and the focus ring 204 while the instrumented substrate 100 is disposed on the chuck 202. For example, the line sensors 108 may receive the illumination 107 generated by the illumination source 106 after the illumination reflects from chuck 202 and/or focus ring 204. The line sensors 108 may receive the illumination 107 which is reflected (e.g., via specular reflection, diffuse reflection, and the like) from chuck 202 and/or focus ring 204 of the chuck edge 207 and/or the focus ring edge 209. The chuck 202 may include a top surface which may be optically rough. For example, the chuck 202 may include a root mean square roughness value in the micron range. The illumination 107 may reflect from the chuck 202 in a diffuse way (e.g., in many angular directions). The focus ring 204 include a top surface which may be optically smooth. For example, the focus ring 204 may include a root mean square roughness value in the nanometer range. The focus ring 204 may reflect the illumination 107 in a specular way (e.g., almost only in a single angular direction). The top surface of the chuck 202 may be aligned at or near the top surface of the focus ring 204. Both the chuck 202 and the focus ring 204 may be imaged to the line sensor 108. Thus, the line images 109 of the chuck 202 and the focus ring 204 may include the chuck edge 207 and/or the focus ring edge 209. For example, an image plane of the line images 109 may include the chuck edge 207 and/or the focus ring edge 209.

The instrumented substrate 100 may determine a position of the chuck edge 207 and/or the focus ring edge 209 in the line images 109 based on the intensity of the line images 109. For example, the chuck edge 207 and/or the focus ring edge 209 in the line images 109 may be defined as a certain percentage of intensity drop and related to a certain pixel number on the line sensors 108, and thus may detected even much more accurate than one pixel size. The illumination 107 may decrease or roll-off in the gap between the chuck edge 207 and the focus ring edge 209. The surface roughness and/or reflectivity (e.g., straylight characteristics) of the chuck 202 and/or the focus ring 204 may determine a ratio of the signal level of illumination 107 reflected from the chuck 202 and/or the focus ring 204 on the line sensor 108. The line images 109 may be used by the instrumented substrate 100 to determine the chuck edge 207 of the chuck 202 is disposed below and in contact with the instrumented substrate 100. The instrumented substrate 100 may capture the chuck edge 207 from each of the position units 104.

Generating the line images 109 while the instrumented substrate 100 is disposed on the chuck 202 may provide a reliable and accurate way to measure the position of the instrumented substrate 100. For example, generating the line images 109 while the instrumented substrate 100 is disposed on the chuck 202 may eliminate errors associated with lift pins and the like.

In embodiments, the position units 104 may directly measure the amount of wafer placement error. The direct measurement may avoid one or more problems associated with setting a scale of the line images 109, including having to know the distance between the line sensor 108 and chuck 202. In embodiments, the position units 104 may not introduce errors associated with spatial distortion, parallax, associated with spatial image sensor implementation.

The substrate-to-chuck offset 113 may indicate the level of concentricity between the substrate center 103 and the chuck center 203. The substrate-to-chuck offset 113 may be a corrective offset needed to center the substrate center 103 to the chuck center 203. The substrate-to-ring offset 115 may indicate the level of concentricity between the substrate center 103 and the focus ring center 205. The substrate-to-ring offset 115 may be a corrective offset needed to center the substrate center 103 to the focus ring center 205. One or more of the functions of the instrumented substrate 100 may be to measure the substrate-to-chuck offset 113 and/or the substrate-to-ring offset 115.

The controller 110 may execute one or more data processing methods to perform autocorrelation between the different locations. In embodiments, the autocorrelation may include determining the edges of the chuck 202 relative to each other. The instrumented substrate 100 may be configured to measure the chuck edge 207. The instrumented substrate 100 may measure the chuck edge 207 relative to the substrate center 103. Asymmetry of the chuck edge 207 relative to the substrate center 103 may be utilized to determine the substrate-to-chuck offset 113. The autocorrelation may include performing trigonometry to find the substrate-to-chuck offset 113 of the substrate center 103 relative to the chuck center 203.

In embodiments, the autocorrelation may include determining the edges of the focus ring 204 relative to each other. In embodiments, the instrumented substrate 100 may be configured to measure the focus ring edge 209. The instrumented substrate 100 may measure the focus ring edge 209 relative to the substrate center 103. Asymmetry of the focus ring edge 209 relative to the substrate center 103 may be utilized to determine the substrate-to-ring offset 115. The autocorrelation may include performing trigonometry to find the substrate-to-ring offset 115 of the substrate center 103 relative to the focus ring center 205.

In embodiments, the substrate handler 206 may be a wafer handler robot. The substrate handler 206 may position the instrumented substrate 100 on the chuck 202. For example, the substrate handler 206 may include one or more robotic mechanisms, end effectors, or the like to position the instrumented substrate 100 on the chuck 202. The substrate handler 206 may undesirably position the instrumented substrate 100 on the chuck 202 with the substrate-to-chuck offset 113. The substrate-to-chuck offset 113 may be due to one or more errors in the substrate handler 206.

The substrate handler 206 may include a computing system operably coupled to the end effector. The computing system may or may not be physically encased within the same device that has the end effector and mechanical linkages that physical place the instrumented substrate 100.

The instrumented substrate 100 may transmit and/or receive various data via the communication interface 116. For example, the instrumented substrate 100 may transmit the substrate-to-chuck offset 113 via the communication interface 116. The instrumented substrate 100 may be configured to communicate with the substrate handler 206 via the communication interface 116. In embodiments, the instrumented substrate 100 may communicate with the substrate handler 206 in real-time.

The controller 110 may transmit the substrate-to-chuck offset 113 and/or the substrate-to-ring offset 115 to the substrate handler 206. Transmitting the substrate-to-chuck offset 113 and/or the substrate-to-ring offset 115 to the substrate handler 206 may involve any operative communication to the substrate handler 206. The instrumented substrate 100 may be operatively coupled to the substrate handler 206 via the communication interface 116. Various data may be conveyed from the instrumented substrate 100 to the substrate handler 206 as feedback for further placement. The substrate handler 206 may receive any of the various measurements from the instrumented substrate 100.

The substrate handler 206 may use the substrate-to-chuck offset 113 and/or the substrate-to-ring offset 115 for optimal semiconductor process performance. For example, the substrate handler 206 may reposition the instrumented substrate 100 on the chuck 202 based on the substrate-to-chuck offset 113 and/or the substrate-to-ring offset 115. The substrate handler 206 may reposition the instrumented substrate 100 to reduce the substrate-to-chuck offset 113 between the substrate center 103 and the chuck center 203 and/or to reduce the substrate-to-ring offset 115 between the substrate center 103 and the focus ring center 205. For example, the substrate handler 206 may align the substrate center 103 to the chuck center 203 based on the substrate-to-chuck offset 113. The substrate handler 206 may reposition the instrumented substrate 100 to center the instrumented substrate 100 on the chuck 202 and/or the focus ring 204.

In embodiments, the substrate handler 206 may position the instrumented substrate 100 among different tools in substrate carriers. For example, the substrate carriers may include a front opening unified pod (FOUP). The instrumented substrate 100 may be housed within the FOUP. The FOUP may include a standard substrate carrier which may be integrated with the substrate processing system 200. The FOUP may provide an environment for storing and transporting the instrumented substrate 100. For example, the substrate handler 206 may pick the substrate handler 206 from the substrate carrier and place the substrate handler 206 on the chuck 202 for processing or post-processing review.

In embodiments, any of the various components of the instrumented substrate 100 may be disposed on and/or embedded in the substrate 102. The components of the instrumented substrate 100 may be disposed on the top surface. The substrate 102 may define one or more cavities. The substrate 102 may define one or more cavities in the top surface. The cavities may be defined by etching, precision grinding, or the like. Any of the various components of the instrumented substrate 100 may be embedded in the cavities, and thereby be embedded in the substrate 102.

The controller 110 may use the sensor readings to detect the presence of the chuck 202. The presence of the chuck 202 may refer to the chuck 202 being disposed below and/or in contact with the substrate 102. In embodiments, the capacitive data 119f may confirm the placement of the instrumented substrate 100 on the chuck 202.

In embodiments, the instrumented substrate 100 may include an optical cement 210. In embodiments, the optical cement 210 may be an optical adhesive. The optical cement 210 may include a selected index of refraction. One or more components of the position units 104 may be fixed to the substrate 102 by the optical cement 210. For example, the components of the position units 104 may be fixed to the substrate 102 within the cavities by the optical cement 210. In embodiments, the optical cement 210 and substrate 102 may include a similar or a same index of refraction, which may prevent the illumination 107 from refracting when passing between the optical cement 210 and substrate 102.

In embodiments, the position units 104 may include a collimator 212. The collimator 212 may be a micro collimator plate, or the like. The line sensor 108 may be in contact with the collimator 212. The collimator 212 may collimate the illumination 107 received by the line sensor 108. The line sensor 108 may be imaged by the collimator 212. In embodiments, the collimator 212 may be near field to the line sensor 108. In this regard, the collimator 212 may include a Fresnel number which is much larger than unity.

The collimator 212 may collimate the illumination 107 in one or more directions. For example, the collimator 212 may collimate the illumination 107 at least in a longitudinal direction (i.e., along the photodiodes of the line sensor 108). The collimator 212 may collimate the illumination 107 at least in the longitudinal direction to allow the line sensor 108 to generate line images 109 which accurately depict the chuck edge 207 and the focus ring edge 209. Thus, the collimator 212 may prevent the illumination 107 from reflecting from the chuck 202 and/or the focus ring 204 at an oblique angle and appearing in the line image 109 in the gap defined between the chuck edge 207 and the focus ring edge 209.

In embodiments, the collimator 212 may collimate the illumination 107 such that only normal rays to pass through to the line sensor 108. The collimator may eliminate all modes of the illumination 107 except the normal mode. The collimator may cause the line sensor 108 to generate the line image 109 as a straight-on image. The collimator 212 may be a lossy mechanism. The collimator may include any suitable design to permit only the normal rays to pass through to the line sensor 108. In embodiments, the collimator 212 may include a collimated hole array. For example, the collimator may include N-arrays of holes etched through a slab on black glass, where N is an integer equal to the number of photodiodes of the line sensor 108. By way of another example, the collimator 212 may include clear glass rods in a black glass matrix. The collimated hole array may act as a pinhole optics over a short distance. The collimated hole array may transfer the illumination 107 from the chuck 202 and/or the focus ring 204 onto the line sensor 108 without magnification or distortion.

In embodiments, the collimator 212 may collimate the illumination 107 in a longitudinal dimension but not in a lateral dimension. Collimating the illumination in the longitudinal dimension but not in the lateral dimension may greatly increases the photon collection. The collimator 212 may include any suitable design for collimating the illumination 107 in the longitudinal dimension but not in the lateral dimension. In embodiments, the collimator 212 may include a stratified collimator. For example, the collimator 212 may include alternating sheets of clear glass and sheets of black glass. The black glass may be opaque to the illumination 107. The alternating sheets of clear glass and sheets of black glass may have the same optical indices and therefore eliminate total internal reflections. Thus, the illumination 107 is collimated after passing through the collimator 212. The alternating sheets of clear glass and sheets of black glass may be aligned to the line sensor 108. For example, each sheet of clear glass may be aligned to each photodiode of the line sensor 108. In this regard, each photodiode of the line sensor 108 may be associated with one of the sheets of clear glass.

In embodiments, the illumination source 106 may be disposed adjacent to the line sensor 108. The illumination source 106 may inject the illumination 107 from the side of the line sensor 108 through the substrate 102 onto a base of the substrate 102. The illumination source 106 may generate the illumination 107 which illuminates the chuck 202 at oblique angles. The diffuse nature of the surface of the chuck 202 and/or the focus ring 204 may cause the illumination 107 to reflect to the line sensor 108.

In embodiments, the substrate 102 may include a diffusive region 214. The diffusive region 214 may be disposed below the illumination source 106. The diffusive region may be patterned into the bottom surface of the substrate 102. The diffusive region 214 may receive the illumination 107 and diffuse the illumination 107. The diffusive region 214 may be disposed adjacent to a clear aperture for the line sensor 108. The clear aperture may be disposed below the line sensor 108. In this regard, the diffusive region 214 may diffuse at least a portion of the illumination 107 towards the line sensor 108. The diffusive region 214 may include any suitable diffusive region. For example, the diffusive region may include a frosted glass and/or a phosphor. The frosted glass may be formed by sand blasting or the like.

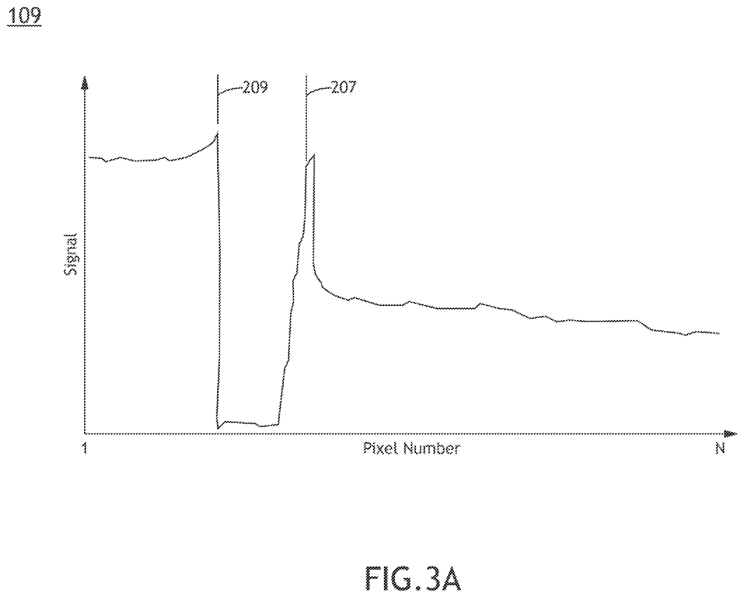

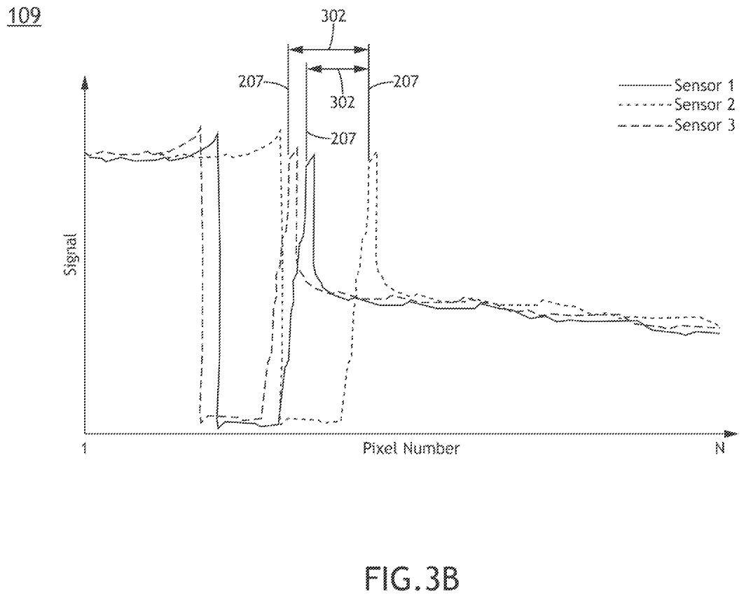

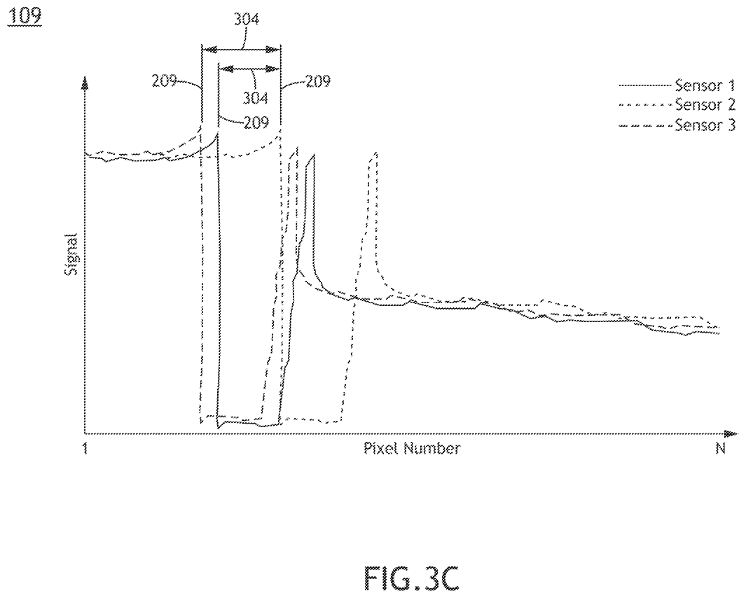

Referring now to FIGS. 3A-3C, the line images 109 are described, in accordance with one or more embodiments of the present disclosure. The horizontal axis of the line images 109 correspond to the pixel number (e.g., the photodiode number). The vertical axis of the line images 109 correspond to a signal value at the pixel.

The signal value of the line images 109 may increase where the illumination 107 reflects to the line sensor 108 and decrease where the illumination 107 does not reflect to the line sensor 108. For example, the signal value may be highest where the line sensor 108 is disposed over the chuck 202 and the focus ring 204, and may be lowest in the gap between the chuck edge 207 and the focus ring edge 209. The line images 109 may appear dark at the location of the gap. For example, the illumination 107 may be reflected by the chuck 202 and the focus ring 204, but may not be reflected by the gap defined between the chuck 202 and the focus ring 204.

The controller 110 may detect the chuck edges 207 and the focus ring edges 209 in the line images 109. The controller 110 may detect the chuck edges 207 and the focus ring edges 209 in the line images 109 based on a change in the signal value. The number of the chuck edges 207 and focus ring edges 209 detected may be based on the number of the position units 104. For example, the instrumented substrate 100 may include three of the position units 104, each including one of the line sensors 108, for a total of three of the chuck edges 207 and focus ring edges 209.

The position of the chuck edges 207 and/or focus ring edges 209 may be asymmetrical in the line images 109. The chuck edges 207 and/or focus ring edges 209 may be detected at different pixels numbers in the line images 109. For example, FIG. 3B depicts the chuck edges 207 detected at different pixel numbers. Each of the chuck edges 207 may be at a same pixel number if there was no substrate-to-chuck offset 113. By way of another example, FIG. 3C depicts the focus ring edges 209 detected at different pixel numbers. Each of the focus ring edges 209 may be at a same pixel number if there was no substrate-to-ring offset 115. The asymmetry in the position of the chuck edges 207 and the position of the focus ring edges 209 may correspond to the substrate-to-chuck offset 113 and the substrate-to-ring offset 115, respectively.

In embodiments, the controller 110 may determine chuck non-concentricity offsets 302. In embodiments, the chuck non-concentricity offsets 302 chuck edge-to-chuck edge offsets. The chuck non-concentricity offsets 302 may be determined based on the chuck edges 207. For example, the chuck non-concentricity offsets 302 may be determined by subtracting the position of one of the chuck edges 207 in the line images 109 from another of the position of one of the chuck edges 207 in the line images 109.

In embodiments, the controller 110 may determine the substrate-to-chuck offset 113 based on the chuck non-concentricity offsets 302. For example, the controller 110 may perform trigonometry using the chuck non-concentricity offsets 302 and the known position of the line sensors 108 on the substrate 102 to determine the substrate-to-chuck offset 113.

In embodiments, the controller 110 may determine one or more focus ring non-concentricity offsets 304. In embodiments, the focus ring non-concentricity offsets 304 may be focus ring edge-to-focus ring edge offsets. The focus ring non-concentricity offsets 304 may be determined based on the focus ring edges 209. For example, the focus ring non-concentricity offsets 304 may be determined by subtracting the position of one of the focus ring edges 209 in the line images 109 from another of the position of one of the focus ring edges 209 in the line images 109.

In embodiments, the controller 110 may determine the substrate-to-ring offset 115 based on the focus ring non-concentricity offsets 304. For example, the controller 110 may perform trigonometry using the focus ring non-concentricity offsets 304 and the known position of the line sensors 108 on the substrate 102 to determine the focus ring non-concentricity offsets 304.

The number of the chuck non-concentricity offsets 302 and/or the focus ring non-concentricity offsets 304 determined may be based on the number of the position units 104. For example, the instrumented substrate 100 may include three of the position units 104, the number of the chuck non-concentricity offsets 302 is two, and the number of focus ring non-concentricity offsets 304 is two.

Although the line images 109 are depicted as being a continuous function, this is not intended as a limitation of the present disclosure. In embodiments, the line images 109 may be depicted as a Dirac-delta function.

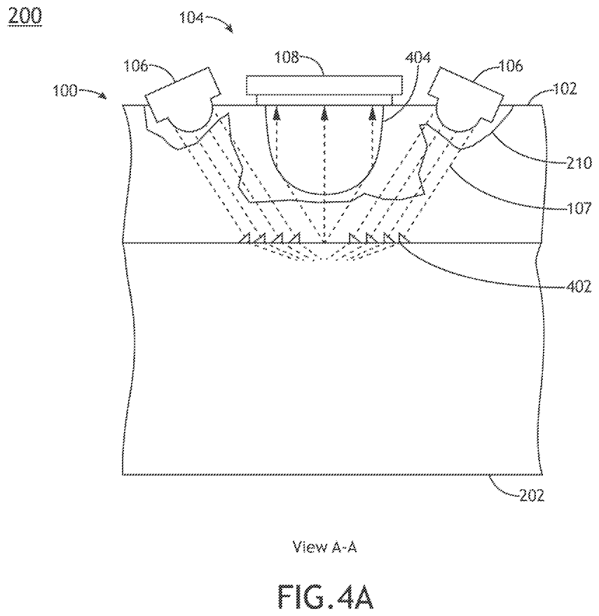

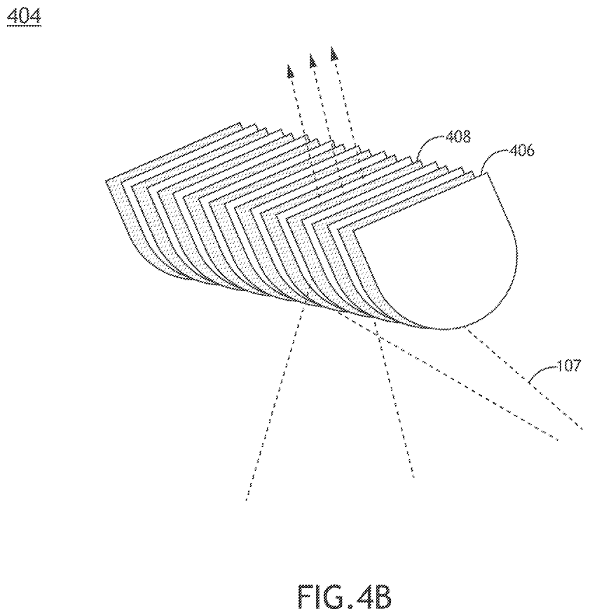

Referring now to FIGS. 4A-4B, the substrate processing system 200 is described, in accordance with one or more embodiments of the present disclosure. In embodiments, the instrumented substrate 100 may include one or more reflectors 402 and/or a cylindrical lens 404.

In embodiments, the illumination source 106 may be angled relative to the substrate 102. For example, the illumination source 106 may be off-axis with the plane of the substrate 102.

In embodiments, the substrate 102 may define one or more of the reflectors 402. In embodiments, the reflectors 402 may be micro-machined reflectors, lens elements, micro-lenses, etched reflectors, micro-machined lens elements, and/or Fresnel lens arrays. The reflectors 402 may be defined in the bottom surface of the substrate 102. The reflectors 402 may receive the illumination 107 from the illumination source 106 and direct the illumination 107. For example, the reflectors 402 may direct the illumination to a region disposed below the line sensor 108. The reflectors 402 may minimize crosstalk between the illumination source 106 and the line sensor 108. The reflectors 402 may be beneficial to direct the illumination 107 to the line sensor 108 when the illumination source 106 is off-axis with the plane of the substrate 102.

The cylindrical lens 404 may include a short focal length. For example, the cylindrical lens 404 may include width of the line of focus of about 25 μm. The cylindrical lens 404 may be coupled to the substrate 102 by the optical cement 210. The inclusion of the cylindrical lens 404 in the optical cement 210 may maintain a function of the cylindrical lens 404 if there is a sufficient optical index difference between the cylindrical lens 404 and the optical cement 210. The cylindrical lens 404 and the optical cement 210 may include the sufficient optical index difference to prevent the cylindrical lens 404 from optically disappearing into the optical cement 210. For example, the illumination 107 may refract when passing between the optical cement 210 and the cylindrical lens 404 thereby causing the cylindrical lens 404 to have a select optical power and/or focal length. The cylindrical lens 404 may collect a significant angle of illumination 107. The line sensor 108 may be imaged by the cylindrical lens 404. The sensitivity of the line sensor 108 may be high by the cylindrical lens 404 collecting the significant angle of illumination 107. Collecting the significant angle of illumination 107 may cause the illumination 107 to bleed over to neighboring photodiodes of the line sensor 108, thus reducing the contrast of the line image 109.

In embodiments, the cylindrical lens 404 may be a stratified cylindrical lens. For example, the cylindrical lens 404 may be made of alternating sheets of clear glass 406 and sheets of black glass 408. The black glass 408 may be opaque to the illumination 107. Alternating the sheets of clear glass 406 and sheets of black glass 408 may create a “zebra” lens that collimates the illumination 107 in the longitudinal direction while collecting the photons from a focus point to the photodiodes of the line sensor 108. The sheets of black glass 408 may block higher mode light arrays that are out-of-plane of the sheets of clear glass 406. Light arrays moving in plane of the clear glass 406 may pass through to the line sensor 108. Thus, the stratified cylindrical lens may function as a directional collimator. The sheets of glass (e.g., clear glass 406, black glass 408) may each have a selected thickness. For example, the thickness of the sheets of glass may be between 5 and 10 μm.

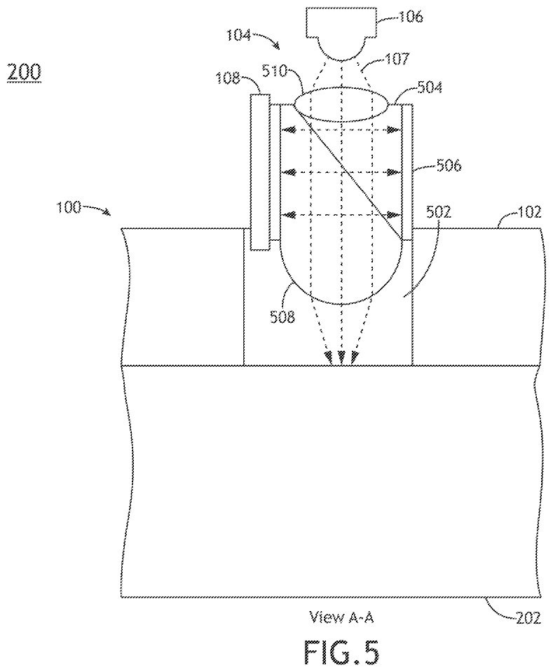

Referring now in particular to FIG. 5, the substrate processing system 200 is described, in accordance with one or more embodiments of the present disclosure. In embodiments, the instrumented substrate 100 may include an optical path configuration in a bright-field mode. The position units 104 may include one or more components causing the optical path configuration to be in the bright-field mode. For example, the position units 104 may include a beam splitter 504, an adsorber 506, an objective lens 508, and/or a condenser lens 510.

The condenser lens 510 may receive the illumination 107 from the illumination source 106. The illumination 107 received may be divergent. The condenser lens 510 may render the illumination 107 which is divergent into parallel beams.

In embodiments, the beam splitter 504 may be a prism, beam combiner, and/or a splitter/combiner. The beam splitter 504 may receive the illumination 107 from the illumination source 106. The beam splitter 504 may be coupled to the condenser lens 510. The beam splitter 504 may receive the illumination 107 from the illumination source 106 via the condenser lens 510. The illumination 107 may pass through the beam splitter 504. The beam splitter 504 may be oriented such that the illumination source 106 may simultaneously direct the illumination 107 to the chuck 202 and/or the focus ring 204 and such that the line sensor 108 may collect the illumination 107 reflected from the chuck 202 and/or the focus ring 204. The beam splitter 504 may bend the optical path of the illumination 107 from vertical to horizontal. Vertical refers to in a direction perpendicular to the normal to the substrate 102. Horizontal refers to in the plane of the substrate 102 (e.g., parallel to the substrate 102). The illumination 107 may be on-axis and/or off-axis illumination. For example, the beam splitter 504 may combine the illumination 107 such that the illumination 107 is on-axis with the illumination source 106, the chuck 202, and/or the focus ring 204. By way of another example, the beam splitter 504 may combine the illumination 107 such that the illumination 107 is off-axis and received by the line sensor 108.

The adsorber 506 may be coupled to the beam splitter 504. The adsorber 506 may receive a portion of the illumination 107 from the beam splitter 504. The adsorber 506 may adsorb a portion of the illumination 107 received from the beam splitter 504 with a portion of the illumination 107 reflected to the beam splitter 504 from the adsorber 506.

The objective lens 508 may collect the illumination 107 from the chuck 202 and/or the focus ring 204. The objective lens 508 may be coupled to the beam splitter 504.

In embodiments, the beam splitter 504, adsorber 506, objective lens 508, and/or condenser lens 510 may be co-3D printed. The beam splitter 504, objective lens 508, and/or condenser lens 510 may be printed as one part from optical plastic of various optical indices. The absorber may also be printed into the position units 104. Small and compact optics may be miniaturized using the co-3D printing. The beam splitter 504, adsorber 506, objective lens 508, and/or condenser lens 510 may serve as a “beam dump” and prevent surface reflection from getting into the line sensor 108. Preventing surface reflection from getting into the line sensor 108 may increase the contrast of the line images 109.

In embodiments, the bottom surface of the substrate 102 may define one or more cutouts 502. In embodiments, the cutouts 502 may be cavities. The cutouts 502 may be defined through the substrate 102 from the top surface to the bottom surface. One or more components of the position units 104 may be disposed in the cutouts 502. For example, at least a portion of the line sensor 108, the beam splitter 504, and/or the objective lens 508 may be disposed in the cutouts 502.

An example of the optical power of the illumination 107 is now provided. The beam splitter 504 may receive 100% of the optical power from the condenser lens 510. The beam splitter 504 may split approximately 50% of the optical power to the adsorber 506 and approximately 50% to the objective lens 508. The adsorber 506 may receive approximately 50% from the beam splitter 504 and reflects less than 1% back to the beam splitter 504. The chuck 202 may receive approximately 50% from the objective lens 508. The chuck 202 may include approximately 20% modulation and approximately 50% reflection. The beam splitter 504 may receive approximately 20 to 26% optical power from the chuck 202 via the objective lens 508. The beam splitter 504 may split the 20 to 26% optical power such that the line sensor 108 and the condenser lens 510 each receive approximately 10 to 13% optical power. In this example, the line sensor 108 may include a contrast of 21% (e.g., 3%/14%). The position units 104 may include a throughput of 12%.

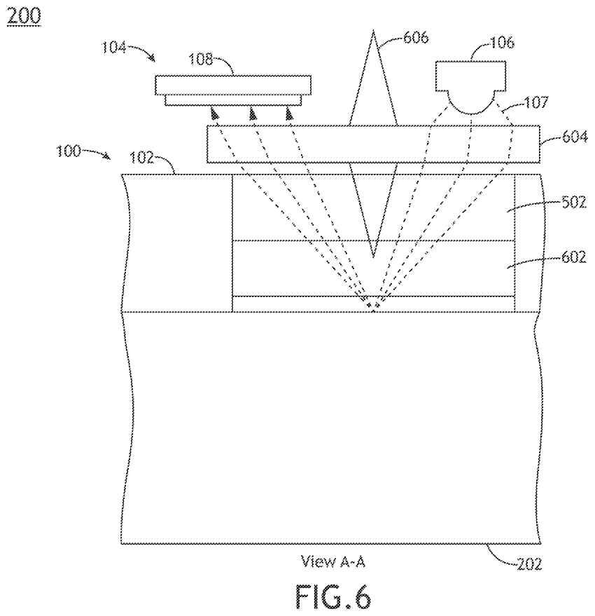

Referring now in particular to FIG. 6, the substrate processing system 200 is described, in accordance with one or more embodiments of the present disclosure. In embodiments, the instrumented substrate 100 may include an optical configuration with a window 602, a meta lens 604, and an adsorber 606.

The windows 602 may be disposed in the cutouts 502. The windows 602 may allow the illumination 107 from the illumination source 106 to reflect from the chuck 202 and/or the focus ring 204. In embodiments, the substrate 102 may be a silicon base substrate if there are cutouts with windows 602 to minimize Electro Static Chucking (ESC) disruptions. The windows 602 may be made of any suitable material, such as, but not limited to, quartz. The windows 602 may be disposed below the meta lens 604. The windows 602 may include a same refractive index as the substrate 102, which may prevent reflections of the illumination 107 at a critical angle.

Although the instrumented substrate 100 is described as including the windows 602, this is not intended as a limitation of the present disclosure. In embodiments, the cutouts 502 may be filled with an optical resin. The cutouts 502 below the meta lens 604 may be filled with the optical resin. The optical resin may make the bottom surface of the substrate 102 planar.

In embodiments, the meta lens 604 may be meta optics. The meta lens 604 may be planar optics that rely on optical structure of a size on the order of the wavelength used by the illumination 107. The meta lens 604 may be made of any suitable material, such as, but not limited to, metal oxide elements. Under magnification, the meta lens 604 may include structures that appear as small pillars of metal and oxides on a transparent substrate of differing height, diameter and spacing. The meta lens 604 may approximate lenses, mirrors, filters, diffractors, and/or modulators.

In embodiments, the line sensors 108 may be imaged by and/or illuminated by the meta lens 604. The meta lens 604 may offset the focus point for the illumination source 106. The meta lens 604 may collect and collimate the illumination 107 returning to the line sensor 108, at an offset position. The meta lens 604 may perform one or more functions of a complex optical system.

The adsorber 606 may receive a portion of the illumination 107 from the meta lens 604. The adsorber 606 may adsorb a significant portion of the illumination 107 received from the meta lens 604. Only a small portion of the illumination 107 may be reflected to the meta lens 604 from the adsorber 606.

Any of the above optical configurations may be combined by those skilled in the art and serves as an example and not a limitation. In embodiments, the position units 104 may include collimator 212. The collimator 212 may be included between the meta lens 604 and the line sensor 108. The collimator 212 may be used to reduce the angle of incidence of the illumination 107.

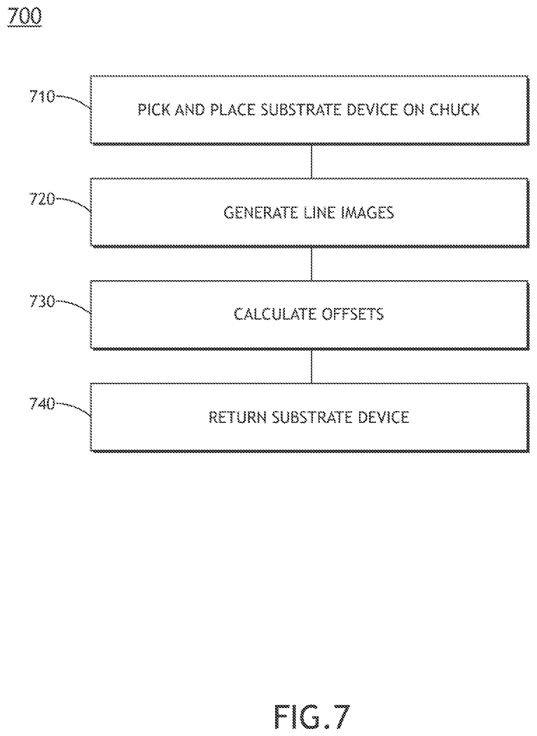

Referring now to FIG. 7, a method 700 is described, in accordance with one or more embodiments of the present disclosure. The method may be for substrate position monitoring. The embodiments and the enabling technologies described previously herein in the context of the instrumented substrate 100 and substrate processing system 200 should be interpreted to extend to the method. It is further noted, however, that the method is not limited to the architecture of the instrumented substrate 100 and substrate processing system 200.

In a step 710, the instrumented substrate 100 may be picked and placed by the substrate handler 206. The instrumented substrate 100 may be picked from a substrate carrier, such as a front opening unified pod (FOUP). The instrumented substrate 100 may be placed on the chuck 202. The chuck 202 may require calibration to determine errors in the placement of the instrumented substrate 100 by the substrate handler 206.

In a step 720, the instrumented substrate 100 may generate the line images 109 from the position units 104. Generating the line images 109 include the illumination source 106 generating the illumination 107 and the line sensors 108 generating the line images 109 based on the illumination 107. Multiple of the line images 109 may be captured from each of the position units 104.

In a step 730, the controller 110 may calculate the substrate-to-chuck offset 113 and/or a substrate-to-ring offset 115. The controller 110 may calculate the substrate-to-chuck offset 113 based on the chuck edges 207 detected in the line images 109. The controller 110 may calculate the substrate-to-ring offset 115 based on the focus ring edges 209 detected in the line images 109.

In a step 740, the substrate handler 206 may return the instrumented substrate 100 to the substrate carrier and receive the substrate-to-chuck offset 113 and/or substrate-to-ring offset 115 from the controller 110. The substrate-to-chuck offset 113 and/or substrate-to-ring offset 115 may be sent through the substrate processing system 200 to a semiconductor process tool. The substrate-to-chuck offset 113 and/or substrate-to-ring offset 115 may be processed by the semiconductor process tool and used to generate a set of correction files which will normalize to a common radius from the substrate center 103. This calibration file may then “zero” out the assembly error and normalize the one-dimensional sensor outputs. The semiconductor process may then apply the calculated centering solution to improve the degree of placement concentricity.

In embodiments, each of the steps may be performed automatically by the substrate processing system 200 so that the instrumented substrate 100 may be accurately positioned efficiently without requiring human intervention. In embodiments, the steps may be iteratively performed to increase the accuracy of the position.

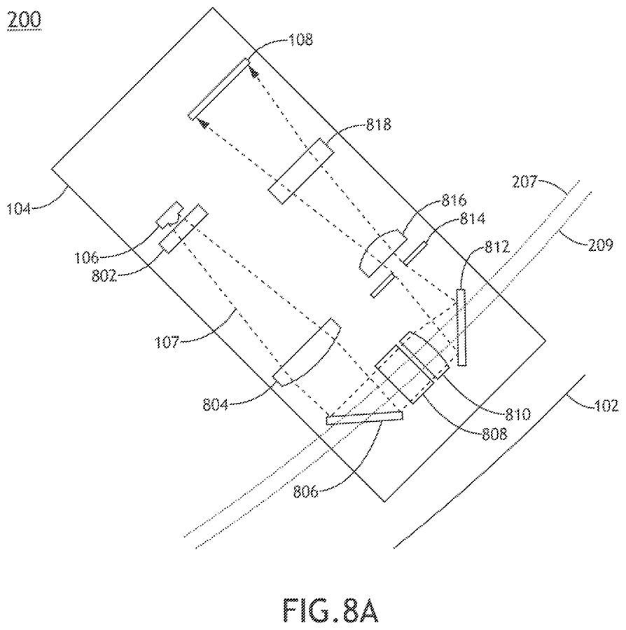

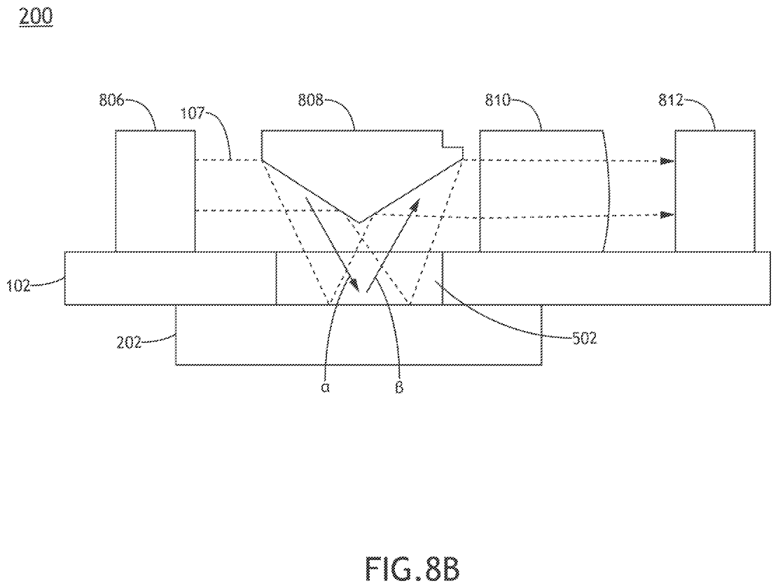

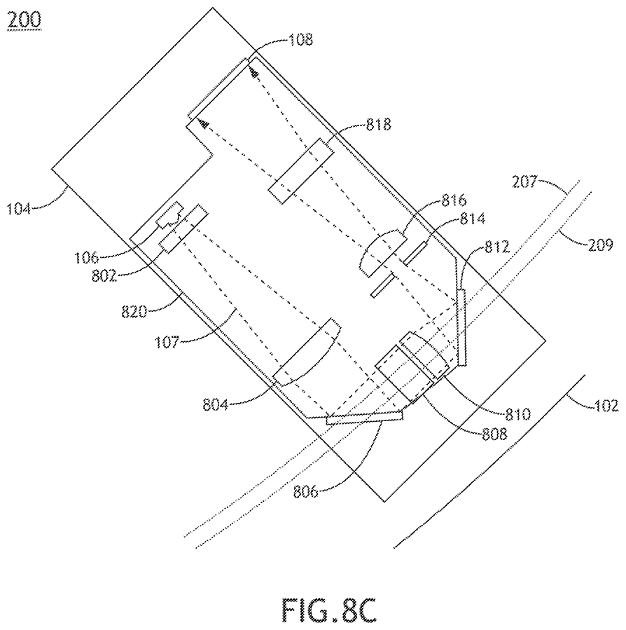

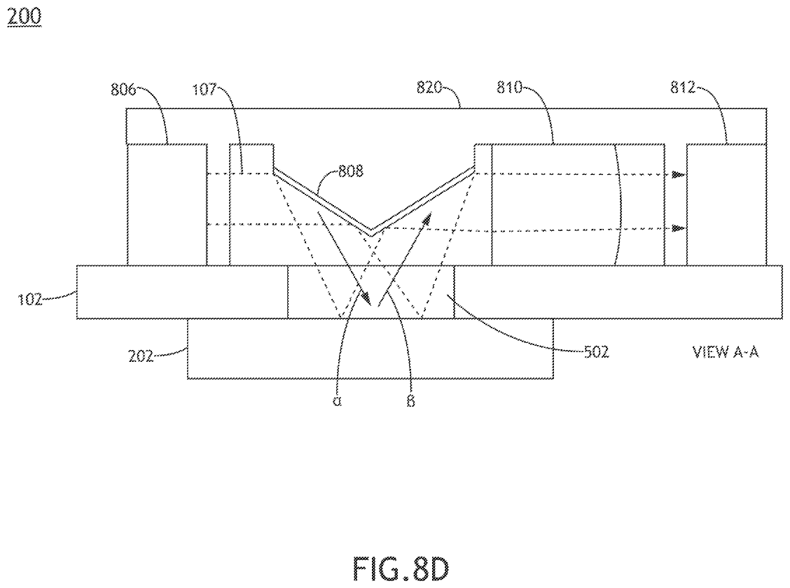

Referring now to FIGS. 8A-8D, the substrate processing system 200 is described, in accordance with one or more embodiments of the present disclosure. In embodiments, the position units 104 may include the illumination source 106, a microlens array 802, a lens 804 (e.g., a first lens), a folding mirror 806 (e.g., a first folding mirror), a prism 808, a lens 810 (e.g., a second lens), a folding mirror 812 (e.g., a second folding mirror), an aperture stop 814, a lens 816 (e.g., a third lens), a cylindrical lens 818, the line sensor 108, and the like. The prism 808 may also be implemented as front surface mirrors positioned at the correct angles.

An optical beam path of the illumination 107 may follow in sequence from the illumination source 106 through the microlens array 802, lens 804, folding mirror 806, prism 808, chuck 202 and/or focus ring 204, lens 810, folding mirror 812, aperture stop 814, lens 816, and cylindrical lens 818 to the line sensor 108. The illumination 107 may follow an illumination path. The illumination path may refer to the path of the illumination 107 from the illumination source 106 up to the chuck 202 and/or focus ring 204. The illumination 107 may follow the illumination path from the illumination source 106 through the microlens array 802, lens 804, folding mirror 806, and prism 808 to the chuck 202 and/or focus ring 204. The illumination 107 may follow an imaging path. The imaging path may refer to the path of the illumination 107 from the chuck 202 and/or focus ring 204 up to the line sensor 108. The illumination 107 may follow an imaging path from the chuck 202 and/or focus ring 204 through the prism 808, lens 810, folding mirror 812, aperture stop 814, lens 816, and cylindrical lens 818 to the line sensor 108.

The microlens array 802 may be disposed between the illumination source 106 and the lens 804. The microlens array 802 may be a cylindrical micro lens array (MLA) that may be create uniformity in the illumination 107 along the long axis of the line sensor 108.

The lens 804 may be disposed between the microlens array 802 and the folding mirror 806. The lens 804 may be a collimating lens which may control a width of the illumination 107.

The folding mirror 806 may be disposed between the lens 804 and the prism 808. The folding mirror 806 may fold the optical beam path of the illumination 107. For example, the folding mirror 806 may fold the illumination path. The folding mirror 806 may fold the illumination at an angle from the lens 804 to the prism 808.

The prism 808 may be disposed between the folding mirror 806 and/or the folding mirror 812. The prism 808 may be disposed above the cutouts 502. The prism 808 may include a high reflection coated prism or the like. The prism 808 may deflect the illumination 107 between the illumination path and the imaging path. For example, the prism 808 may deflect the illumination 107 from the illumination path to the chuck 202 and/or the focus ring 204, thereby deflecting the illumination 107 from the illumination path. By way of another example, the prism 808 may deflect the illumination 107 from the chuck 202 and/or the focus ring 204 to the folding mirror 812, thereby deflecting the illumination 107 into the imaging path.

The prism 808 may be configured such that the illumination 107 may reflect from the chuck edges 207 and focus ring edge 209. The illumination 107 may or may not reflect from the sides and/or bottom of the chuck 202 and/or the focus ring 204. The contrast of the chuck edges 207 and focus ring edge 209 in the line images 109 may be improved where the illumination 107 does not reflect from the sides and/or bottom of the chuck 202 and/or the focus ring 204. The illumination 107 may be imaged to the chuck 202 and/or the focus ring 204 off-axis to the perpendicular direction. For example, the illumination 107 may include one or more incidence angles (a) onto and/or reflection angles (B) from the chuck 202 and/or focus ring 204. The incidence angles (a) onto and/or reflection angles (B) may be off-axis to a plane of the substrate 102. Imaging the illumination 107 to the chuck 202 and/or the focus ring 204 off-axis to the perpendicular may cause the illumination 107 to reflect from the chuck edges 207 and focus ring edge 209 but not to reflect from the sides and/or bottom of the chuck 202 and/or the focus ring 204 back to the line sensor 108.

In embodiments, the incidence angles (a) may be different than the reflection angles (B). The prism 808 may define the incidence angles (a) and the reflection angles (B) at the different angles. For example, a first face of the prism 808 may reflect the illumination 107 from the folding mirror 806 to the chuck 202 and/or focus ring 204. By way of another example, a second face of the prism 808 may reflect the illumination 107 from the chuck 202 and/or focus ring 204 to the lens 810. The first face and second face of the prism 808 may define the incidence angles (a) and the reflection angles (B), respectively. Defining the incidence angles (a) and the reflection angles (B) at the different angles may cause the specular reflection of the illumination 107 from the focus ring 204 to not pass the aperture stop 814. Since the reflectivity of the chuck 202 may be much more diffuse, the illumination 107 may pass from the chuck 202 through the aperture stop 814 even when the incidence angles (a) may be different than the reflection angles (B). Thus, defining the incidence angles (a) and the reflection angles (B) at the different angles may reduce a signal level of the focus ring 204 while maintaining the signal level of the chuck 202 in the line images 109.

The lens 810 may be disposed between the prism 808 and the folding mirror 812.

The folding mirror 812 may be disposed between the lens 810 and the aperture stop 814. The folding mirror 812 may fold the optical beam path of the illumination 107. For example, the folding mirror 812 may fold the imaging path. The folding mirror 812 may fold the illumination at an angle from the lens 810 to the aperture stop 814.

The folding mirror 806 and/or the folding mirror 812 may fold the illumination 107 at a select angle, such as, but not limited to, a forty-five-degree angle. The instrumented substrate 100 may have a selected height. The selected height may be less than a value, such as, but not limited to, 3.5 mm. The optical beam path of the illumination 107 may be folded such that the height of the instrumented substrate 100 is below the selected height.

The aperture stop 814 may be disposed between the folding mirror 812 and the lens 816. The aperture stop 814 may determine a numerical aperture of the position units 104. For example, the aperture stop 814 may determine the numerical aperture of the illumination 107 on the imaging path.

The lens 816 may be disposed between the folding mirror 812 and the aperture stop 814. The lens 810 and/or the lens 816 may form an image of the chuck edge 207 and/or the focus ring edge 209 onto the line sensor 108.

The cylindrical lens 818 may be disposed between the lens 816 and the line sensor 108. The cylindrical lens 818 may spread the image of the chuck 202 in the y-direction of the line sensor 108. Spreading the image of the chuck 202 may reduce a tolerance sensitivity of the line sensor 108 in a vertical direction extending from the surface of the substrate 102. Since, the line sensor 108 consists of a line, the performance of the line sensor 108 may be sensitive to any lateral misplacement in y. In the vertical-direction no optical resolution is necessary. Hence, the cylindrical lens 818 may spreads the image of the chuck 202 in the vertical direction to reduce tolerance sensitivity.

In embodiments, one or more collimators, meta lenses, and illuminations sources may be combined to form the various functions of the microlens array 802, lens 804, folding mirror 806, prism 808, lens 810, folding mirror 812, aperture stop 814, lens 816, and/or cylindrical lens 818. For example, the lens 804 and/or the lens 810 may be a collimator. The lens 804 and/or the lens 810 may collimate the illumination 107 such that only normal rays to pass through the lens 804. The lens 804 and/or lens 810 may eliminate all modes of the illumination 107 except the normal mode. For instance, the lens 804 may collimate the illumination 107 from the microlens array 802. By way of another instance, the lens 810 may collimate the illumination 107 from the prism 808. By way of another example, any of the microlens array 802, lens 804, lens 810, lens 816, and/or cylindrical lens 818 may be a meta lens.

In embodiments, the position units 104 may include an optical assembly 820 (see FIGS. 8C-8D). The microlens array 802, the lens 804, the folding mirror 806, the prism 808, the lens 810, the folding mirror 812, the aperture stop 814, the lens 816, and/or the cylindrical lens 818 may be disposed below the optical assembly 820. The optical assembly 820 may mechanically support the microlens array 802, the lens 804, the folding mirror 806, the prism 808, the lens 810, the folding mirror 812, the aperture stop 814, the lens 816, and/or the cylindrical lens 818. For example, at least two of the microlens array 802, the lens 804, the folding mirror 806, the prism 808, the lens 810, the folding mirror 812, the aperture stop 814, the lens 816, or the cylindrical lens 818 may be part of a monolithic molded assembly (e.g., part of a monolithic molded assembly with the optical assembly 820). For instance, each of the microlens array 802, the lens 804, the folding mirror 806, the prism 808, the lens 810, the folding mirror 812, the aperture stop 814, the lens 816, and the cylindrical lens 818 may be part of a monolithic molded assembly.

In embodiments, the folding mirror 806, the prism 808, and/or the folding mirror 812 may be formed by coating the optical assembly 820 with a metallic film. The metallic film may cause the illumination 107 to reflect from the folding mirror 806, the prism 808, and/or the folding mirror 812. In embodiments, the folding mirror 806 and/or the folding mirror 812 are exterior folding mirrors which are supported by the optical assembly 820, such that the optical assembly 820 may be in the optical beam path of the illumination 107.

The optical assembly 820 may include an index of refraction which is different than the lens 804, the lens 810, the lens 816, and/or the cylindrical lens 818. For example, the optical assembly 820 may include an index of refraction which may be lower than the index of refraction of the lens 804, the lens 810, the lens 816, and/or the cylindrical lens 818. The illumination 107 may couple between free-space (e.g., not the optical assembly 820) and the lens 804, the lens 810, the lens 816, and/or the cylindrical lens 818 to maintain the optical power of the lens 804, the lens 810, the lens 816, and/or the cylindrical lens 818.

In embodiments, the illumination 107 may couple from the microlens array 802 into free-space, couple from free-space into the lens 804, couple from the lens 804 into free-space, couple from free-space into the optical assembly 820, reflect from the folding mirror 806, couple from the optical assembly 820 into free-space, and reflect from the prism 808 up to the chuck 202 and/or focus ring 204 at the incidence angles (a).

In embodiments, the illumination 107 may reflect from the chuck 202 and/or focus ring 204 at the reflection angles (B), reflect from the prism 808, couple from free-space into the optical assembly 820, couple from the optical assembly 820 into the lens 810, couple from the lens 810 into the optical assembly 820, reflect from the folding mirror 812, couple from the optical assembly 820 into free-space, pass through the aperture stop 814, couple from free-space into the lens 816, couple from the lens 816 into free-space, couple from free-space into the cylindrical lens 818, couple from the cylindrical lens 818 into free-space, up to the line sensor 108.

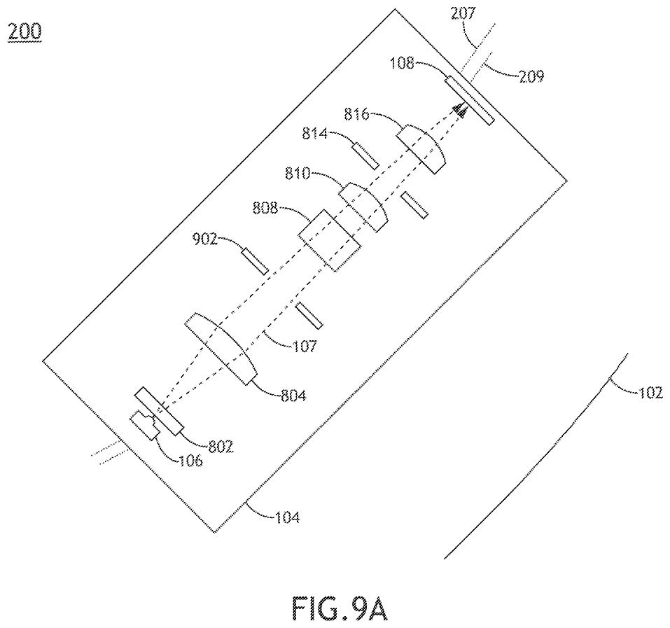

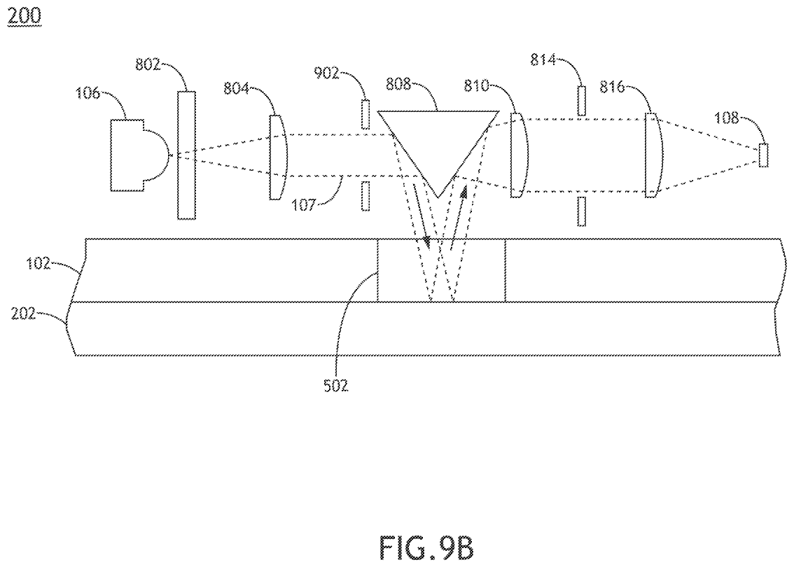

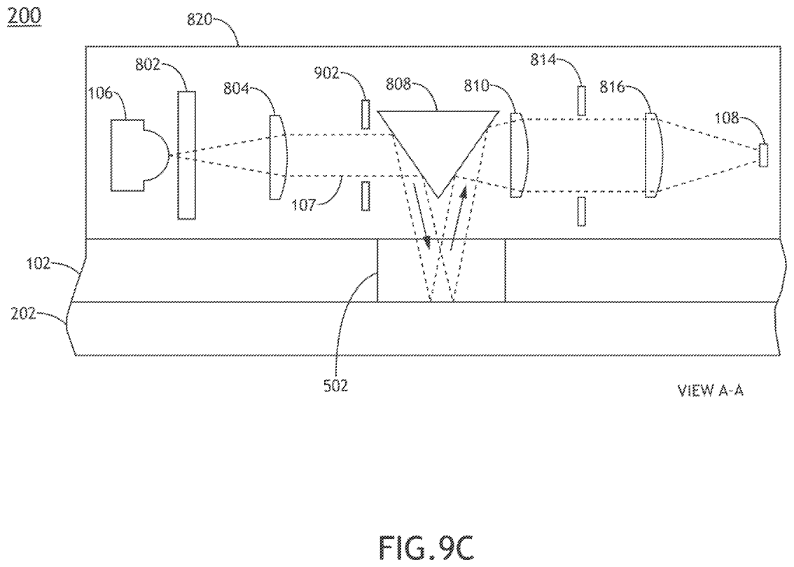

Referring now to FIGS. 9A-9C, the substrate processing system 200 is described, in accordance with one or more embodiments of the present disclosure. In embodiments, the position units 104 may include the illumination source 106, microlens array 802, lens 804 (e.g., a first lens), aperture stop 902 (e.g., a first aperture stop), lens 810 (e.g., a second lens), aperture stop 814 (e.g., a second aperture stop), lens 816 (e.g., a third lens), the line sensor 108, and the like.

An optical beam path of the illumination 107 may follow in sequence from the illumination source 106 through the microlens array 802, lens 804, aperture stop 902, prism 808, chuck 202 and/or focus ring 204, lens 810, aperture stop 814, and lens 816 to the line sensor 108. The illumination 107 may follow the illumination path from the illumination source 106 through the microlens array 802, lens 804, aperture stop 902, and prism 808 up to the chuck 202 and/or focus ring 204. The illumination 107 may follow an imaging path from the chuck 202 and/or focus ring 204 through the prism 808, lens 810, aperture stop 814, and lens 816 to the line sensor 108.

The microlens array 802 may be disposed between the illumination source 106 and the lens 804. The microlens array 802 may be a cylindrical micro lens array (MLA) that may be create uniformity in the illumination 107 along the long axis of the line sensor 108.

The lens 804 may be disposed between the microlens array 802 and the aperture stop 902. The lens 804 may be a collimating lens which may control a width of the illumination 107.

The aperture stop 902 may be disposed between the lens 804 and the prism 808. The aperture stop 902 may control the numerical aperture of the illumination 107 on the illumination path. In this example, the illumination 107 may be directed to the chuck 202 and/or focus ring 204 on the illumination path without the use of the folding mirror 806.

The prism 808 may be disposed between the aperture stop 902 and the chuck 202 and/or focus ring 204. The prism 808 may include a high reflection coated prism or the like. The prism 808 may deflect the illumination 107 between the illumination path and the imaging path. For example, the prism 808 may deflect the illumination 107 from the illumination path to the chuck 202 and/or the focus ring 204, thereby deflecting the illumination 107 from the illumination path. By way of another example, the prism 808 may deflect the illumination 107 from the chuck 202 and/or the focus ring 204 to the folding mirror 812, thereby deflecting the illumination 107 into the imaging path.

In embodiments, the incidence angles (a) may be different than the reflection angles (B). The prism 808 may define the incidence angles (a) and the reflection angles (B) at the different angles.

The lens 810 may be disposed between the prism 808 and the aperture stop 814.

The aperture stop 814 may be disposed between the lens 810 and the lens 816. The aperture stop 814 may determine a numerical aperture of the position units 104. For example, the aperture stop 814 may determine the numerical aperture of the illumination 107 on the imaging path.

The lens 816 may be disposed between the aperture stop 814 and the line sensor 108. The lens 810 and/or the lens 816 may form an image of the chuck edge 207 and/or the focus ring edge 209 onto the line sensor 108.

In embodiments, the position units 104 may include the optical assembly 820 which may form a monolithic block with the microlens array 802, lens 804, the aperture stop 904, the prism 808, the lens 810, the aperture stop 814, the lens 816, and/or the cylindrical lens 818. For example, the optical assembly 820 may be co-molded with microlens array 802, lens 804, the aperture stop 904, the prism 808, the lens 810, the aperture stop 814, the lens 816, and/or the cylindrical lens 818. However, co-molding the optical assembly 820 with the microlens array 802, lens 804, the aperture stop 904, the prism 808, the lens 810, the aperture stop 814, the lens 816, and/or the cylindrical lens 818 may reduce an optical power of the position units 104.

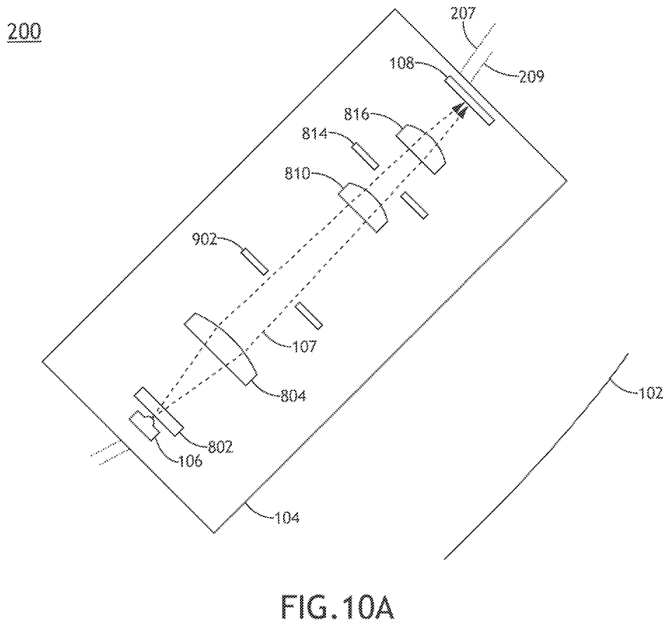

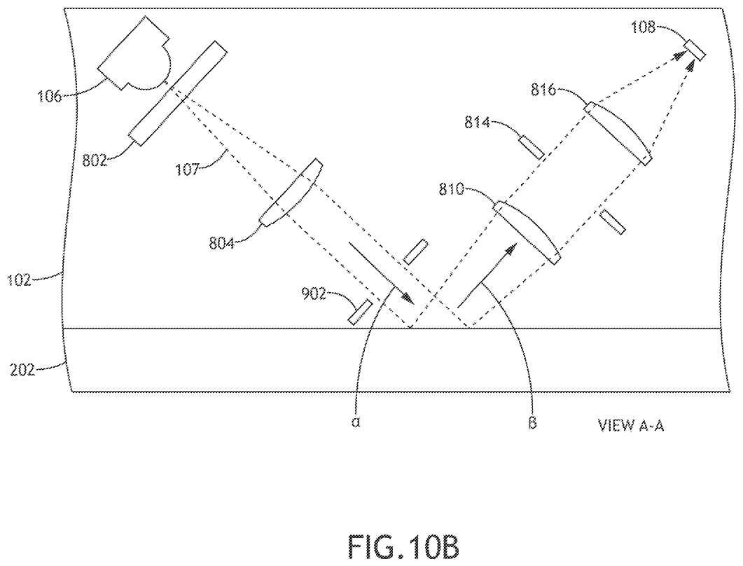

Referring now to FIGS. 10A-10B, the substrate processing system 200 is described, in accordance with one or more embodiments of the present disclosure. In embodiments, the position units 104 may include the illumination source 106, microlens array 802, lens 804 (e.g., a first lens), aperture stop 902 (e.g., a first aperture stop), lens 810 (e.g., a second lens), aperture stop 814 (e.g., a second aperture stop), lens 816 (e.g., a third lens), the line sensor 108, and the like.

An optical beam path of the illumination 107 may follow in sequence from the illumination source 106 through the microlens array 802, lens 804, aperture stop 902, chuck 202 and/or focus ring 204, lens 810, aperture stop 814, and lens 816 to the line sensor 108. The illumination 107 may follow the illumination path from the illumination source 106 through the microlens array 802, lens 804, and aperture stop 902 up to the chuck 202 and/or focus ring 204. The illumination 107 may follow an imaging path from the chuck 202 and/or focus ring 204 through the lens 810, aperture stop 814, and lens 816 to the line sensor 108.

The microlens array 802 may be disposed between the illumination source 106 and the lens 804. The microlens array 802 may be a cylindrical micro lens array (MLA) that may be create uniformity in the illumination 107 along the long axis of the line sensor 108.

The lens 804 may be disposed between the microlens array 802 and the aperture stop 902. The lens 804 may be a collimating lens which may control a width of the illumination 107.

The aperture stop 902 may be disposed between the lens 804 and the chuck 202 and/or the focus ring 204. The aperture stop 902 may control the numerical aperture of the illumination 107 on the illumination path. In this example, the illumination 107 may be directed to the chuck 202 and/or focus ring 204 on the illumination path without the use of the folding mirror 806 and/or prism 808.

The illumination 107 may include one or more incidence angles (a) onto and/or reflection angles (B) from the chuck 202 and/or focus ring 204. The incidence angles (a) onto and/or reflection angles (B) may be off-axis to a plane of the substrate 102. Imaging the illumination 107 to the chuck 202 and/or the focus ring 204 off-axis to the perpendicular may cause the illumination 107 to reflect from the chuck edges 207 and focus ring edge 209 but not to reflect from the sides and/or bottom of the chuck 202 and/or the focus ring 204 back to the line sensor 108. In embodiments, the incidence angles (a) and reflection angles (B) may be at a same angle, causing the specular reflected light from the focus ring 204 to pass the aperture stop 814 and hit the line sensor 108 such that the signal level from the focus ring 204 may be much higher than the signal level of the chuck 202. In this situation the additional signal of the focus ring edge 209 may disturb the detecting the chuck edge 207.

The lens 810 may be disposed between the chuck 202 and/or focus ring 204 and the aperture stop 814.

The aperture stop 814 may be disposed between the lens 810 and the lens 816. The aperture stop 814 may determine a numerical aperture of the position units 104. For example, the aperture stop 814 may determine the numerical aperture of the illumination 107 on the imaging path.

The lens 816 may be disposed between the aperture stop 814 and the line sensor 108. The lens 810 and/or the lens 816 may form an image of the chuck edge 207 and/or the focus ring edge 209 onto the line sensor 108.

Referring generally again to FIGS. 1A-10B. It is noted that the arrangement and number of the position units 104 depicted are not limiting and are provided merely for illustrated purposes. The position units 104 may be configured in several patterns, shapes, and quantities.

The position units 104 may include many optical configurations. For example, the position units 104 may include optical cement 210, collimator 212, diffusive region 214, one or more reflectors 402, cylindrical lens 404, beam splitter 504, adsorber 506, objective lens 508, condenser lens 510, window 602, meta lens 604, and/or adsorber 606. Any of the various optical elements may be manufactured using any suitable process. For example, the various optical elements may be fabricated using 3D printing or the like. The line sensor 108 may be imaged by any of the various components of the position units 104. To be imaged by refers to the line sensor 108 receiving the illumination 107 via the component.

In embodiments, the controller 110 may determine a need for a preventative maintenance (PM) cycle based on the substrate-to-chuck offset 113 and/or the substrate-to-ring offset 115. For example, the focus ring 204 may be determined to be asymmetric to the chuck 202 based on the substrate-to-chuck offset 113 and the substrate-to-ring offset 115. The asymmetry may be utilized to diagnose the need for the preventative maintenance cycle.

Although much of the present disclosure is described in the context of the substrate 102 being a round wafer, this is not intended as a limitation of the present disclosure. The substrate 102 could be any symmetrical polygon where an effective center may be established using the sensors. For example, the substrate 102 may include a square, triangle, or any symmetrical polygon where an effective center may be established.

The chuck 202 may or may not include a round feature at the center of the chuck 202. The instrumented substrate 100 may determine the substrate-to-chuck offset 113 without requiring the chuck 202 to include the round feature at the center of the chuck 202. The instrumented substrate 100 thus provides a universal solution to a wide range of the chucks 202 with different design configurations.

The position units 104 may include any of the various optical components, such as, but not limited to, the collimator 212, the diffusive region 214, the reflectors 402, the cylindrical lens 404, the beam splitter 504, the adsorber 606, the microlens array 802, the lens 804, the folding mirror 806, the prism 808, the lens 810, the folding mirror 812, the aperture stop 814, the lens 816, the cylindrical lens 818, the optical assembly 820, and/or the aperture stop 902. The optical components may be made using a fabrication process. For example, the optical components may be made by molding (e.g., injection molding, glass molding, blank molding), casting, embossing, and the like. For instance, one or more of the microlens array 802, the lens 810, the lens 816, and/or the cylindrical lens 818 may be a molded lens. The optical components may be made of a material. For example, the optical components may be made of a plastic, glass, or the like.

In embodiments, the substrate processing system 200 may include a user interface. The user interface may be communicatively coupled to the controller 110. In one embodiment, the user interface may include, but is not limited to, one or more desktops, laptops, tablets, and the like. In another embodiment, the user interface may include a display used to display data of the system to a user. The display of the user interface may include any display known in the art. For example, the display may include, but is not limited to, a liquid crystal display (LCD), an organic light-emitting diode (OLED) based display, or a CRT display. Those skilled in the art should recognize that any display device capable of integration with a user interface is suitable for implementation in the present disclosure. In another embodiment, a user may input selections and/or instructions responsive to data displayed to the user via a user input device of the user interface.

The one or more processors may include any processor or processing element known in the art. For the purposes of the present disclosure, the term “processor” or “processing element” may be broadly defined to encompass any device having one or more processing or logic elements (e.g., one or more micro-processor devices, one or more application specific integrated circuit (ASIC) devices, one or more field programmable gate arrays (FPGAs), or one or more digital signal processors (DSPs)). In this sense, the one or more processors may include any device configured to execute algorithms and/or instructions (e.g., program instructions stored in memory). In one embodiment, the one or more processors may be embodied as a desktop computer, mainframe computer system, workstation, image computer, parallel processor, networked computer, or any other computer system configured to execute a program. Moreover, different subsystems of the system may include a processor or logic elements suitable for carrying out at least a portion of the steps described in the present disclosure. Therefore, the above description should not be interpreted as a limitation on the embodiments of the present disclosure but merely as an illustration. Further, the steps described throughout the present disclosure may be carried out by a single controller or, alternatively, multiple controllers.

In embodiments, a controller may include one or more controllers housed in a common housing or within multiple housings. In this way, any controller or combination of controllers may be separately packaged as a module suitable for integration into a system. Further, the controllers may analyze data received from detectors and feed the data to additional components within the system or external to the system.

The memory medium may include any storage medium known in the art suitable for storing program instructions executable by the associated one or more processors. For example, the memory medium may include a non-transitory memory medium. By way of another example, the memory medium may include, but is not limited to, a read-only memory (ROM), a random-access memory (RAM), a magnetic or optical memory device (e.g., disk), a magnetic tape, a solid-state drive and the like. It is further noted that memory medium may be housed in a common controller housing with the one or more processors. In one embodiment, the memory medium may be located remotely with respect to the physical location of the one or more processors and controller. For instance, the one or more processors of controller may access a remote memory (e.g., server), accessible through a network (e.g., internet, intranet and the like).

As used throughout the present disclosure, the term “substrate” generally refers to a substrate formed of a semiconductor or non-semiconductor material (e.g., thin filmed glass, or the like). For example, a semiconductor or non-semiconductor material may include, but is not limited to, monocrystalline silicon, gallium arsenide, indium phosphide, or a glass material. A substrate may include one or more layers. For example, such layers may include, but are not limited to, a resist (including a photoresist), a dielectric material, a conductive material, and a semiconductive material. Many different types of such layers are known in the art, and the term sample as used herein is intended to encompass a substrate on which all types of such layers may be formed. One or more layers formed on a substrate may be patterned or un-patterned. For example, a substrate may include a plurality of dies, each having repeatable patterned features. Formation and processing of such layers of material may ultimately result in completed devices. Many different types of devices may be formed on a substrate, and the term substrate as used herein is intended to encompass a substrate on which any type of device known in the art is being fabricated. Further, for the purposes of the present disclosure, the term substrate and wafer should be interpreted as interchangeable. In addition, for the purposes of the present disclosure, the terms patterning device, mask and reticle should be interpreted as interchangeable.

It is further contemplated that each of the embodiments of the methods described above may include any other step(s) of any other method(s) described herein. In addition, each of the embodiments of the method described above may be performed by any of the systems described herein.

One skilled in the art will recognize that the herein described components operations, devices, objects, and the discussion accompanying them are used as examples for the sake of conceptual clarity and that various configuration modifications are contemplated. Consequently, as used herein, the specific exemplars set forth and the accompanying discussion are intended to be representative of their more general classes. In general, use of any specific exemplar is intended to be representative of its class, and the non-inclusion of specific components, operations, devices, and objects should not be taken as limiting.

As used herein, directional terms such as “top,” “bottom,” “over,” “under,” “upper,” “upward,” “lower,” “down,” and “downward” are intended to provide relative positions for purposes of description, and are not intended to designate an absolute frame of reference. Various modifications to the described embodiments will be apparent to those with skill in the art, and the general principles defined herein may be applied to other embodiments

With respect to the use of substantially any plural and/or singular terms herein, those having skill in the art can translate from the plural to the singular and/or from the singular to the plural as is appropriate to the context and/or application. The various singular/plural permutations are not expressly set forth herein for sake of clarity.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected,” or “coupled,” to each other to achieve the desired functionality, and any two components capable of being so associated can also be viewed as being “couplable,” to each other to achieve the desired functionality. Specific examples of couplable include but are not limited to physically mixable and/or physically interacting components and/or wirelessly interactable and/or wirelessly interacting components and/or logically interacting and/or logically interactable components.

Furthermore, it is to be understood that the invention is defined by the appended claims. It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” and the like). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art will recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C, and the like” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, and the like). In those instances where a convention analogous to “at least one of A, B, or C, and the like” is used, in general such a construction is intended in the sense one having skill in the art would understand the convention (e.g., “a system having at least one of A, B, or C” would include but not be limited to systems that have A alone, B alone, C alone, A and B together, A and C together, B and C together, and/or A, B, and C together, and the like). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

It is believed that the present disclosure and many of its attendant advantages will be understood by the foregoing description, and it will be apparent that various changes may be made in the form, construction and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. An instrumented substrate comprising:
a substrate comprising a substrate center;
a power source;
a communication interface;
at least three position units, wherein each of the at least three position units comprise:
an illumination source configured to generate illumination; and
a line sensor configured to generate a plurality of line images based on the illumination, wherein the line sensor is aligned to the substrate center; and
a controller comprising:
a memory maintaining program instructions; and
one or more processors configured to execute the program instructions causing the one or more processors to:
receive the plurality of line images; and
determine a substrate-to-chuck offset between the substrate center and a chuck center based on the plurality of line images.

2. The instrumented substrate of claim 1, wherein the one or more processors determine the substrate-to-chuck offset by:
detecting a plurality of chuck edges in the plurality of line images;
determine a plurality of chuck non-concentricity offsets between the plurality of chuck edges; and
determine the substrate-to-chuck offset based on the plurality of chuck non-concentricity offsets.

3. The instrumented substrate of claim 1, wherein the program instructions cause the one or more processors to determine a substrate-to-ring offset based on the plurality of line images.

4. The instrumented substrate of claim 1, wherein the substrate is a round substrate.

5. The instrumented substrate of claim 1, wherein the substrate comprises at least one of quartz, glass, silicon, silicon nitride, carbon fiber stabilized epoxy matrices, or a combination thereof.

6. The instrumented substrate of claim 1, comprising one or more additional sensors, wherein the one or more additional sensors are configured to generate one or more sensor readings, wherein the controller is configured to detect a presence of a chuck based on the one or more sensor readings.

7. The instrumented substrate of claim 6, wherein the one or more additional sensors comprise at least one of a pressure sensor, a multi-axis accelerometer, a multi-axis angular rate sensor, a temperature sensor, a light sensor, or a capacitive sensor.

8. The instrumented substrate of claim 6, wherein, in response to the one or more sensor readings satisfying a trigger threshold, the one or more processors cause the illumination source to generate the illumination and cause the line sensor to generate the plurality of line images.

9. The instrumented substrate of claim 1, wherein the substrate comprises a diffusive region, wherein the diffusive region is disposed below the illumination source.

10. The instrumented substrate of claim 1, wherein each of the at least three position units comprise a collimator, wherein the line sensor is imaged by the collimator.

11. The instrumented substrate of claim 10, wherein the collimator comprises a collimated hole array.

12. The instrumented substrate of claim 10, wherein the collimator comprises a stratified collimator.

13. The instrumented substrate of claim 10, wherein the collimator is near field to the line sensor.

14. The instrumented substrate of claim 1, wherein one or more reflectors are defined in a bottom surface of the substrate.

15. The instrumented substrate of claim 1, wherein each of the at least three position units comprise a cylindrical lens, wherein the line sensor is imaged by the cylindrical lens.

16. The instrumented substrate of claim 15, wherein the cylindrical lens is a stratified cylindrical lens that functions as a directional collimator.

17. The instrumented substrate of claim 1, wherein each of the at least three position units comprise an optical element, wherein the optical element comprises a beam splitter, an adsorber, an objective lens, and a condenser lens, wherein the line sensor is imaged by the optical element.

18. The instrumented substrate of claim 1, wherein each of the at least three position units comprise a meta lens, wherein the line sensor is imaged by the meta lens.

19. The instrumented substrate of claim 1, wherein each of the at least three position units comprise a microlens array, a first lens, a first folding mirror, a prism, a second lens, a second folding mirror, an aperture stop, a third lens, and a cylindrical lens; wherein the illumination follows an illumination path from the illumination source through the microlens array, the first lens, the first folding mirror, and the prism to a chuck; wherein the illumination follows an imaging path from the chuck through the prism, the second lens, the second folding mirror, the aperture stop, the third lens, and the cylindrical lens to the line sensor.

20. The instrumented substrate of claim 19, wherein the illumination comprises one or more incidence angles onto and one or more reflection angles from the chuck; wherein the one or more incidence angles are different than the one or more reflection angles.

21. The instrumented substrate of claim 19, wherein at least two of the microlens array, the first lens, the first folding mirror, the prism, the second lens, the second folding mirror, the aperture stop, the third lens, or the cylindrical lens are part of a monolithic molded assembly.

22. The instrumented substrate of claim 1, wherein each of the at least three position units comprise microlens array, a first lens, a first aperture stop, a prism, a second lens, a second aperture stop, and a third lens; wherein the illumination follows an illumination path from the illumination source through the microlens array, the first lens, the first aperture stop, and the prism to a chuck; wherein the illumination follows an imaging path from the chuck through the prism, the second lens, the second aperture stop, and the third lens to the line sensor.

23. The instrumented substrate of claim 22, wherein the illumination comprises one or more incidence angles onto and one or more reflection angles from the chuck; wherein the one or more incidence angles are different than the one or more reflection angles.

24. The instrumented substrate of claim 1, wherein each of the at least three position units comprise a microlens array, a first lens, a first aperture stop, a second lens, a second aperture stop, and a third lens; wherein the illumination follows an illumination path from the illumination source through the microlens array, the first lens, and the first aperture stop to a chuck; wherein the illumination follows an imaging path from the chuck through the second lens, the second aperture stop, and the third lens to the line sensor.

25. The instrumented substrate of claim 24, wherein the illumination comprises one or more incidence angles onto and one or more reflection angles from the chuck; wherein the one or more incidence angles are at a same angle as the one or more reflection angles.

26. A substrate processing system comprising:
a chuck comprising a chuck center;
a focus ring;
a substrate handler; and
an instrumented substrate comprising:
a substrate comprising a substrate center;
a power source;
a communication interface;
at least three position units, wherein each of the at least three position units comprise:
an illumination source configured to generate illumination; and
a line sensor configured to generate a plurality of line images based on the illumination, wherein the line sensor is aligned to the substrate center; and
a controller comprising:
a memory maintaining program instructions; and
one or more processors configured to execute the program instructions causing the one or more processors to:
receive the plurality of line images; and
determine a substrate-to-chuck offset between the substrate center and the chuck center based on the plurality of line images.

27. The substrate processing system of claim 26, wherein the substrate handler is configured to receive the substrate-to-chuck offset from the instrumented substrate; wherein the substrate handler is configured to reposition the instrumented substrate on the chuck based on the substrate-to-chuck offset.
